(19) United States
(12) Patent Application Publication
(10) Pub. No.: US 2010/0124109 A1
(43) Pub. Date: May 20, 2010

(54) SEMICONDUCTOR MEMORY DEVICE FOR STORING MULTI LEVEL DATA

(76) Inventors: Mitsuaki HONMA, Yokohama-shi (JP); Noboru Shibata, Kawasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/562,439

(22) Filed: Sep. 18, 2009

(30) Foreign Application Priority Data
Nov. 20, 2008 (JP) 2008-296864

(51) Int. Cl. G11C 16/04; G11C 7/10

(52) U.S. Cl. 365/185.03; 365/189.05; 365/185.18

(57) ABSTRACT

A memory cell array is configured so that a plurality of memory cells which are connected to a word line and a bit line store one value out of n values (n is a natural number of 2 or more) in one memory cell and are arranged in a matrix. A control circuit controls electronic potentials of the word line and the bit line in response to input data to write data in the memory cells. When writing data in the first memory cell of the memory cell array, the control circuit varies a writing level on the basis of writing data to write in a second memory cell adjacent to the first memory cell.

### CROSS-REFERENCE TO RELATED APPLICATIONS

This application is based upon and claims the benefit of priority from prior Japanese Patent Application No. 2008-296864, filed Nov. 20, 2008, the entire contents of which are incorporated herein by reference.

### BACKGROUND OF THE INVENTION

1. Field of the Invention

The present invention relates to a semiconductor memory device, and relates to, for example, a NAND flash memory for storing a plurality of bits in one memory cell.

2. Description of the Related Art

In a NAND flash memory, a plurality of memory cells are serially connected between a source line and a bit line, which results in a configuration of a NAND unit. In the NAND flash memory, data is sequentially written in order of memory cells which are closest to the source line. Therefore, writing of data in a memory cell positioned on the bit line side which is closer to a memory cell in which data is already written poses such a problem that a threshold voltage of the memory cell in which the data is already written is shifted due to capacity coupling.

Such effect due to capacity coupling also occurs in a plurality of memory cells connected to one word line. That is, in the case of, for example, three memory cells connected to the one word line, when the data is written in a memory cell between two memory cells, the threshold voltages of the two memory cells shift the threshold voltage of a writing cell.

The shift of the threshold value caused by the writing in the adjacent cells becomes remarkable because of an increase in capacity coupling due to the fining of elements. To compensate for this capacity coupling, a method for finely writing data after first roughly writing it is disclosed (e.g., Jpn. Pat. Appln. KOKAI Publication No. 2007-323731). However, the reading by detecting the state of rough writing poses an increase in writing time. Thus, a semiconductor memory device which can compensate for the shift of a threshold distribution of memory cells due to the capacity coupling of cells adjacent to each other, and which can write data at high speed, is desired.

### BRIEF SUMMARY OF THE INVENTION

According to a first aspect of the invention, there is provided a semiconductor memory device comprising: a memory cell array in which a plurality of memory cells connected to a word line and a bit line are arranged in a matrix, each of the plurality of memory cells of which stores one value out of n values (n is a natural number of 2 or more); and a control circuit configured to control electrical potentials of the word line and the bit line in response to input data, and to write data in the memory cells, wherein: when writing the data in a first memory cell of the memory cell array, the control circuit varies a writing level on the basis of writing data to write in a second memory cell adjacent to the first memory.

According to a second aspect of the invention, there is provided a program method of a semiconductor memory device for storing one value out of n values (n is a natural number of 2 or more), respectively, in a plurality of memory cells which are arranged in a matrix, comprising: writing data in a first memory cell of the memory cell array in response to input data; and varying a verify level on the basis of writing data to write in a second memory adjacent to the first memory.

### BRIEF DESCRIPTION OF THE SEVERAL VIEWS OF THE DRAWING

FIG. 1 is a schematic block diagram of a semiconductor memory device according to an embodiment;

FIG. 2 shows an example of a memory cell array and a sense amplifier circuit;

FIG. 3 is a circuit diagram showing an example of a sense amplifier unit;

FIG. 4 is a circuit diagram showing an example of a data control unit;

FIG. 5 is a view showing relationships of shifts of threshold voltages due to a threshold voltage distribution and capacitances of coupling of memory cells adjacent to each other;

FIG. 6 is a view showing a first embodiment, and showing an example of a writing operation based on the shift of memory cells due to capacity coupling of memory cells adjacent to each other;

FIGS. 7, 8, and 9 are flowcharts showing writing operations regarding the first embodiment, respectively;

FIG. 10 is a view showing an example of a threshold voltage distribution after compensation for capacity coupling regarding the first embodiment;

FIG. 11 is a view showing a relationship between a verify level and data according to a second embodiment;

FIGS. 12, 13, and 14 are flowcharts showing examples of verify operations according to the second embodiment, respectively;

FIG. 15 is a view showing a relationship between a verify level and data according to a third embodiment;

FIGS. 16A and 16B are views regarding the third embodiment, and showing changes in meanings of data with data conversion operations;

FIG. 17 is a view showing an example of a writing sequence of the third embodiment;

FIGS. 18A to 18D are views showing examples of writing operations of the third embodiment, respectively;

FIGS. 19, 20, and 21 are flowcharts showing examples of verify and data conversion operations of the third embodiment, respectively;

FIG. 22 is a view showing a schematic operation of a fourth embodiment;

FIG. 23 is a view showing an example of a writing sequence according to the fourth embodiment;

FIGS. 24A and 24B are views showing examples of data conversion operations according to the fourth embodiment;

FIG. 25 is a view showing writing order according to a fifth embodiment;

FIGS. 26A and 26B are views showing examples of writing operations according to the fifth embodiment;

FIG. 27 is a view showing another example of the writing operation according to the fifth embodiment;

FIG. 28 is a view showing a writing order according to a sixth embodiment;

FIGS. 29 and 30 are views showing examples of writing operations according to the sixth embodiment;

FIGS. 31 and 32 are views showing examples of programs and verify operations according to the sixth operations;

FIG. 33 is a view showing writing order according to a seventh embodiment;

FIG. 34 is a view showing an example of a writing operation according to the seventh embodiment;

FIGS. 35A and 35B are views regarding an eighth embodiment and showing a relationship of data in adjacent columns;

FIG. 36 is a view regarding the eighth embodiment and showing a relationship among data in adjacent columns and the number of times of additional writing;

FIG. 37 is a view regarding the eighth embodiment and showing an example of a data conversion operation;

FIG. 38 is a circuit diagram showing an example of a modification of the sense amplifier unit;

FIG. 39 is a configuration view showing an application to which the semiconductor memory device according to the embodiment is applied; and

FIGS. 40 to 48 are a diagram showing an example of other applications.

### DETAILED DESCRIPTION OF THE INVENTION

Hereinafter, embodiments of the invention will be described with reference to the accompanying drawings.

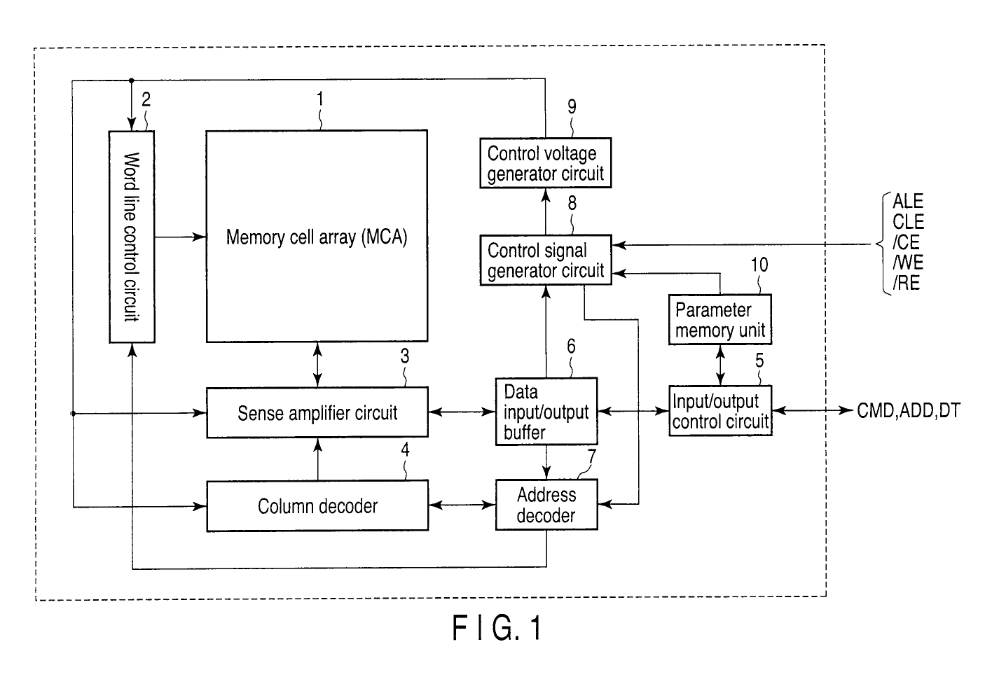

FIG. 1 shows a schematic configuration of a semiconductor memory device according to an embodiment of the invention.

In FIG. 1, a memory cell array 1 is composed of a NAND flash memory configured to store, for example, 2-bit data in one memory cell. That is, as mentioned below, the memory cell array 1 includes a plurality of memory cells each composed of a plurality of bit lines, a plurality of word lines, a shared source line, and, for example, EEPROM cells configured to electrically rewrite data, and to be arranged in a row direction and a column direction. A word line control circuit 2 is connected to the word lines of the array 1, and selectively drives the word lines. A sense amplifier circuit 3 is connected to the bit lines of the array 1, as mentioned below, and has data reading and writing functions and a function for converting writing data into the remaining number of times of writing. A column decoder 4 outputs a column selection signal for selecting the bit lines of the array 1 in response to an output signal from an address decoder 7.

An input output control circuit 5 receives various commands, address signals and writing data supplied from the outside. For writing data, writing data is supplied to the sense amplifier circuit 3 through a data input output buffer 6 from the input output control circuit 5. When reading the data, the data read by the sense amplifier circuit 3 is supplied to the control circuit 5 through the data input output buffer 6 to be output outside from the control circuit 5.

The address signals supplied from the input output control circuit 5 to the input output buffer 6 are supplied to the word line control circuit 2 and the column decoder 4.

The commands supplied from the input output control circuit 5 to the input output buffer 6 are supplied to a control signal generator circuit 8. External control signals such as chip enable signal /CE, a write enable signal /WE, a read enable signal /RE, an address latch enable signal ALE and a command latch enable signal CLE are supplied from the outside. The control signal generator circuit 8 generates control signals for controlling sequences of data writing and data erasing, and control signals for controlling data reading on the basis of external control signals and commands to be supplied in response to an operation mode. These control signals are supplied to a control voltage generator circuit 9 and the address decoder 7.

The control voltage generator circuit 9 generates voltages such as a reading voltage, a writing voltage, a verify voltage, an erasing voltage, which are necessary for various operations of the memory cell array 1, the sense amplifier circuit 3 and the column decoder 4 in response to various control signals supplied from the control signal generator circuit 8.

A parameter memory unit 10 is connected to the input output control circuit 5 and to the control signal generator circuit 8, and stores parameters suitable for the quality of a chip decided in a test process.

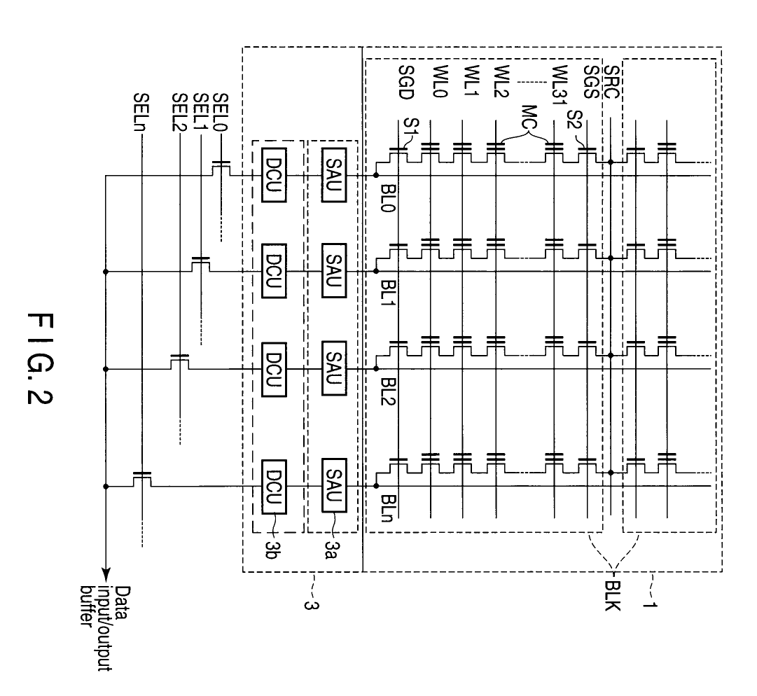

FIG. 2 shows a configuration example of the memory cell array 1 and the sense amplifier circuit 3 shown in FIG. 1. The memory cell array 1, as shown by a dotted line, includes a plurality of blocks BLKs. These blocks compose erasing units. A plurality of NAND cells are arranged in each block BLK. One NAND cell is composed of a memory cell MC consisting of, for example, 32 serially connected EEPROMs, and selection gate transistors S1, S2. The selection gate transistor S1 is connected to a bit line BLO, and the selection gate transistor S2 is connected to a source line SRC. The control gate of the memory cell (MC) arranged on each row is commonly connected to word lines WL0, WL1, WL2-WL31. The selection gate transistor S1 is commonly connected to a select line SGD and the selection gate transistor S2 is commonly connected to a select line SGS.

The sense amplifier circuit 3 includes a plurality of sense amplifier units (SAUs) 3a and a plurality of data control units (DCUs) 3b. Each sense amplifier unit 3a is connected to bit lines BL0, BL1, BL2-BLn. Each data control unit 3b is connected to each sense amplifier unit 3a. When reading the data, each sense amplifier unit 3a detects the data read from the memory cell to the bit line to store the data in the amplifier unit 3a. Each data control unit 3b is connected to the data input output buffer through transistors to be operated in accordance with column selection signals SEL0-SELn.

In a writing operation (also referred to as a program operation), a reading operation, and a program verify operation (also referred to as a verify operation), a bit line connected to the sense amplifier unit 3a is selected, and a single word line is selected. Applying writing or reading voltages to all memory cells connected to the selected word line performs writing or reading operations all together.

The data control unit 3b stores the writing data supplied from the outside, and stores the data read from the sense amplifier unit 3a. Further, when writing the data, the data control unit 3b performs an operation to convert the writing data into data corresponding to the number of times of application of writing voltage.

In FIG. 2, while the sense amplifier unit 3a is connected to each bit line, the configuration is not limited to this configuration, and one sense amplifier unit 3a, for example, may be provided for two bit lines. While the control circuit 3b is connected to each sense amplifier unit 3a, the configuration is not limited to this configuration, and one data control unit 3b, for example, may be provided for eight sense amplifiers, and the data control unit 3b may be selectively connected to the sense amplifier unit 3a.

FIG. 3 shows an example of the sense amplifier unit (SAU) 3a. The SAU 3a is composed of a plurality of P-channel MOS transistors (referred to as PMOSs) 20, 21, 22, 23, a plurality of N-channel MOS transistors (referred to as NMOSs) 31, 32, 33, 34, 35, 36, 37, and a latch circuit (LAT1) composed of, for example, a clocked inverter circuit.

The source of the PMOS 20 is connected to the node of the PMOS 20 to which a power source Vdd is applied, and the drain of the PMOS 20 is connected to a data control unit (DCU) 3b through the PMOS 21, the NMOS 31, 32. The gate of the PMOS 20 is connected to a node INV of a below mentioned latch circuit LAT 1. A signal BLC 1 is supplied to the gate of the PMOS 20, and signals BLC 2, BLC 3 are supplied to the gates of the NMOS 31, 32, respectively. Connection nodes of the NMOS 31 and the NMOS 32 are connected to the bit line BL, and are grounded through the NMOSs 33, 34. The gate of the NMOS 33 is connected to the node INV of the latch circuit LAT 1, the NMOS 33 is controlled by the data held in the latch circuit LAT 1. Further, a signal DIS is supplied to the gate of the NMOS 34.

The source of the PMOS 22 is connected to the node to which the power source Vdd is supplied, the drain of the PMOS 22 is connected to the data control unit 3b through the PMOS 23, the NMOS 36 and the NMOS 37. A signal BLC 4 is supplied to the gate of the PMOS 22, the gate of the PMOS 23 is connected to the connection nodes of the PMOS 21 and the NMOS 31 through the NMOS 35. A signal XXL is supplied to the gate of the NMOS 35, and a reset signal RST is supplied to the gate of the NMOS 31. A signal BLC 5 is supplied to the gate of the NMOS 37. The latch circuit LAT 1 is connected to the NMOS 36 in parallel.

Operations of the foregoing sense amplifier will be schematically described.

(Writing Operation)

When the data is written in the memory cell (MC), the reset signal RST is firstly set to a high level (referred to as an H level) once, and the latch circuit LAT 1 is reset. That is, the node INV of the latch circuit LAT 1 is set to the H level. After this, the signals BLC 1, BLC 4, DIS are set to low levels (referred to as L levels).

Then, the signals BLC 2, BLC 3, XXL are set to H levels, the signal BLC 4 is set to an L level, and thus, the data is taken from the data control unit 3b. If the data is equivalent to an L level “0” indicating writing, the gate of the PMOS 23 is set to the L level, and the PMOS 23 is brought into an on state. Thereby, an H level “1” is set to the latch circuit LAT 1. If the data has the H level “1” indicating non-writing, the PMOS 23 is brought into an off state. Thereby, the L level “0” is set to the latch circuit LAT 1. That is, for writing data, the node INV of the latch circuit LAT 1 is set to the H level, and when not set for writing the data, the node INV is set to the L level.

Next, the signals BLC 1, BLC 3, DIS, and XXL are set to the L levels, and the signal BLC 2 is set to the H level, and the bit line BL is charged to the H level. After this, the signal DIS is set to the H level. Then, if the node INV of the latch circuit LAT 1 is equivalent to the H level indicating the writing, the NMOS 33 is turned on, and electrical charges on the bit line are discharged through the NMOSs 33, 34. If the node INV of the latch circuit LAT 1 is set to the L level indicating non-writing, the electrical potential on the bit line is held at the H level because the NMOS 33 turns off. After this, when the select line SGD of the selection gate transistor S1 connecting the bit lines and the NAND cell shown in FIG. 2 is set to the H level, the electrical potential of the bit line is transferred to the channel of the memory cell. At the same time, a writing voltage Vpgm is applied to a word line of the selected memory cell. Thereby, when the memory cell is a writing cell, the channel is set to the L level (Vss), and the word line is set to the writing voltage Vpgm, the writing is executed. When the memory cell is a non-writing cell, the channel is set to the H level (Vdd-Vth: Vth is a threshold voltage of the selection gate transistor), and the word line is set to the writing voltage Vpgm, so that the writing is not executed.

(Reading Operation)

To read data from the memory cell, the reset signal RST is set to the H level once, and the latch circuit LAT 1 is reset. After this, the signals BLC 1, BLC 3, DIS, and XXL are set to the L level, the signal BLC 2 is set to H level, and the bit line is charged to the H level. After this, the signal BLC 2 is set to the L level and the reading level is supplied to the selection word line. If the threshold voltage of the memory cell is higher than the reading level, the memory cell is in an off state, and the bit line is held at the H level. If the threshold voltage of the memory cell is lower than the reading level, the memory cell is brought into the on state, and the electrical charges on the bit line are discharged. Thus, the bit line is set to the L level. Next, the signal BLC 3 is set to the H level and the electrical potential of the bit line is read by means of the data control unit 3b.

(Program Verify Operation)

After the writing operation, a program verify operation for verifying the threshold voltage of the memory cell is performed in the almost same manner as that of the reading operation. In this case, after the charging of the bit cell to the H level, a predetermined verify voltage is applied to the selection word line. If the threshold voltage of the memory cell reaches the verify voltage, the memory cell is brought into the off state. Thereby, the electrical potential of the bit line is held at the H level. If the threshold voltage does not reach the verify voltage, the memory cell is brought into the on state. Thus, the electrical potential of the bit line set to the L level.

In this state, the signals BLC 1, BLC2, XXL are set to the H levels, the signals BLC4, BLC3, DIS, and RST are set to the L levels, and the electrical potential of the bit line BL is held in the latch circuit LAT 1. That is, if the threshold voltage of the memory cell reaches the verify voltage, and if the electrical potential of the bit line BL is set to the H level, the PMOS 23 is brought into the off state. Thereby, the latch circuit LAT1 holds the L level. if the threshold voltage of the memory cell does not reach the verify voltage, and if the electrical potential of the bit line BL is set to the L level, the PMOS 23 is brought into the on state. Thereby, the latch circuit LAT1 holds the H level. That is, when the verification passed, the latch circuit LAT1 sets the electrical potential at the node INV to the L level, and when the verification is not passed, the latch circuit LAT1 sets the electrical potential at the node INV to the H level.

In the state where the signal BLC 5 is set to the H level and the NMOS 37 comes into the on state, an inversion node INVn of the latch circuit LAT 1 transfers its data to the data control unit 3b.

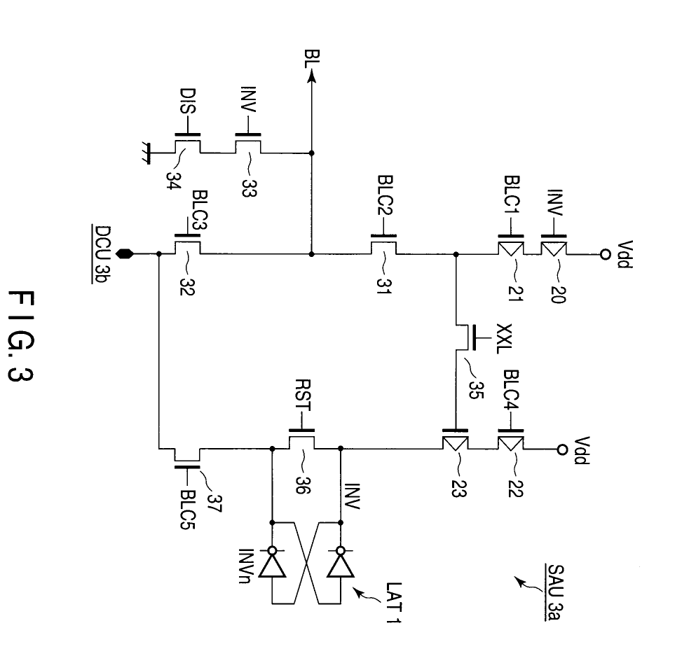

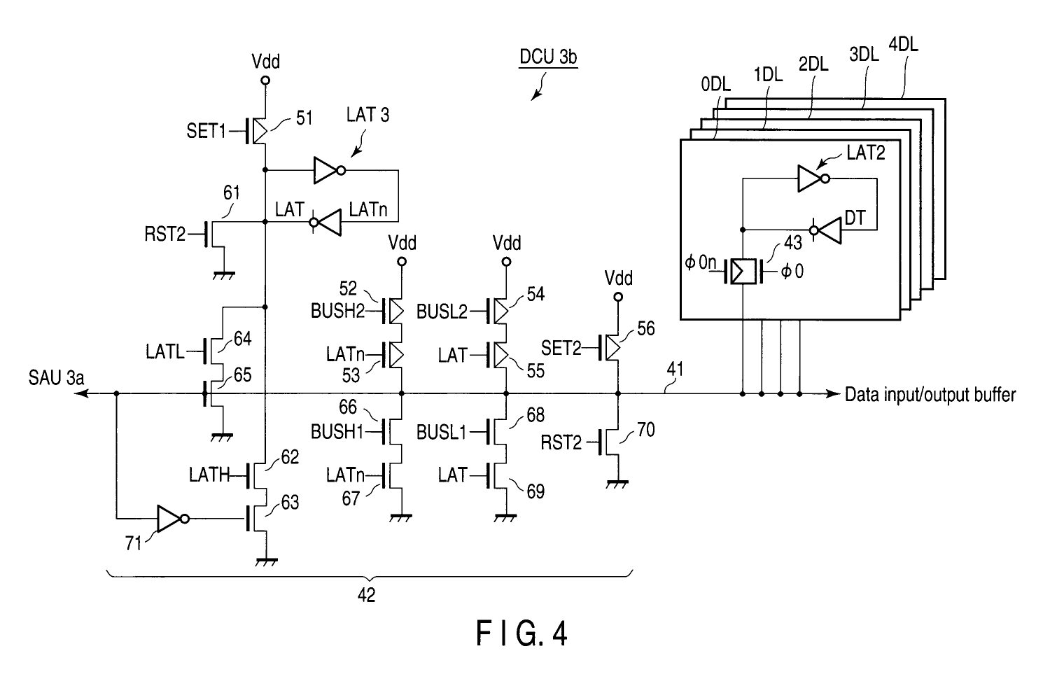

FIG. 4 shows an example of the data control unit (DCU) 3b. The data control unit 3b includes, for example, five data latch circuits 0DL, 1DL, 2DL, 3DL, 4DL, a bus 41, and a data formation circuit 42.

One end of the bus 41 is connected to the sense amplifier unit 3a, and the other end thereof is connected to the data input output buffer 6.

The data latch circuit 0DL is composed of a latch circuit LAT 2 and a transfer gate 43. The latch circuit LAT 2 is connected to the bus 41 through the transfer gate 43. The transfer gate 43 is controlled by a signal Φ and its inversion signal Φn. The data latch circuits 1DL, 2DL, 3DL, and 4DL have the same configuration as that of the data latch circuit 0DL, and signals to be supplied to the transfer gates 43 are different from one another. Therefore, each data latch circuit 0DL, 1DL, 2DL, 3DL, and 4DL is selectively connectable to the bus 41.

The data formation circuit 42 is composed of a latch circuit LAT 3, PMOSs 52-56, NMOSs 61-70 and an inverter circuit 71. The source of the PMOS 51 is connected to the node to which the power source Vdd is supplied. A set signal SET 1 is supplied to the gate of the PMOS 51, and the drain is connected to the latch circuit LAT 3. Further, the drain of the PMOS 51 is grounded through the NMOS 61, and grounded through the NMOSs 62, 63. A reset signal RST 2 is supplied to the gate of the NMOS 61, and a signal LATH is supplied to the gate of the NMOS 62. The gate of the NMOS 63 is connected to the output terminal of the inverter 71 of which the input terminal is connected to the bus 41. Further, the drain of the PMOS 51 is grounded through the NMOSs 64, 65. A signal LATL is supplied to the gate of the NMOS 64 and the gate of the NMOS 65 is connected to the bus 41.

A serial circuit of the PMOSs 52, 53, a serial circuit of the PMOSs 54, 55, and the PMOS 56 are connected between the node and the bus 41 to which the power source Vdd is supplied.

A signal BUSH 2 is supplied to the gate of the PMOS 52, and the gate of the PMOS 53 is connected to the node LATn of the latch circuit LAT 3. The PMOSs 52, 53 are circuits to charge the bus 41 to the H level in response to the signal BUSH 2 and the electrical potential of the node LATn of the LAT 3.

A signal BUSH 2 is supplied to the gate of the PMOS 54, and the gate of the PMOS 55 is connected to the node LAT of the latch circuit LAT 3. The PMOSs 54, 55 are circuits to charge the bus 41 to the H level in response to the signal BUSH 2 and the electrical potential of the node LAT of the LAT 3.

A set signal SET 2 is supplied to the gate of the PMOS 56. The PMOS 56 is a circuit to charge the bus 41 to the H level in response to the set signal SET 2.

A serial circuit of the NMOSs 66, 67, a serial circuit of the NMOSs 68, 69, and the NMOS 70 are connected between the bus 41 and the ground.

The BUSH 1 is supplied to the gate of the NMOS 66, and the gate of the NMOS 67 is connected to the node LATn of the LAT 3. The NMOSs 66, 67 are circuits to discharge the bus 41 to the L level in response to the signal BUSH 1 and the electrical potential of the node LATn of the LAT 3.

A signal BUSL 1 is supplied to the gate of the NMOS 68, and the gate of the NMOS 69 is connected to the node LAT of the latch circuit LAT 3. The NMOSs 68, 69 are circuits to discharge the bus 41 to the L level in response to the signal BUSL1 and the electrical potential of the node LAT of the latch circuit LAT 3.

The reset signal RST 2 is supplied to the gate of the NMOS 70. The NMOS 70 is a circuit to discharge the bus 41 to the L level in response to the reset signal RST 2.

The data control unit 3b holds the data in the data latch circuits 0DL, 1DL, 2DL, 3DL, 4DL, and can process the held data. That is, as mentioned below, the data control unit 3b may perform operations equivalent to, for example, AND, NAND, OR and inversion operations of the held data.

(Basic Operation of Data Control Unit)

A basic operation of the foregoing data control unit 3b will be described. The 2-bit writing data supplied from the data input output buffer 6 is latched in the data latch circuit 1D1, 2DL for each 1-bit. Here, the data latch circuits 1D1, 2DL hold, for example, data of a lower page and an upper page, respectively. The data latch circuit 0DL is used for holding flag data showing the passage of the verification. The data in the data latch circuits 0DL, 1D1, 2DL, 3DL, and 4DL can be transferred to the bus 41 through the transfer gate 43.

To take in the data on the bus 41 into the latch circuit LAT 3, the control unit 3b sets the reset signal RST 2 to the H level to turn on the NMOSs 61, 70, and resets the bus 41 and the latch circuit LAT 3 to the L level.

Next, the control unit 3b sets the set signal SET 1 to the L level to turn on the PMOS 51, and sets the latch circuit LAT 3 to the H level. When taking the data into the latch circuit LAT 3, the latch circuit LAT 3 is firstly set to the H level. After this, for example, any one of the data latch circuits 0DL-4DL transfers the data to the bus 41. After this, for example, from any one of the data latch circuits 0DL-4DL, the control unit 3b transfers the data to the bus 41. In this state, the signal LATH is set to the H level. If the data on the bus 41 has the H level, the output signal from the inverter circuit 71 is turned into a low level, and the NMOS 63 is left in the off state. Therefore, the latch circuit LAT 3 is still H level.

If the bus 41 has the L level, the output signal from the inverter circuit 71 is turned into the H level, and the NMOS 63 turns into the on state. Therefore, the latch circuit LAT 3 is discharged through the NMOSs 62, 63 and is turned into the L level.

Next, operations for inverting the data on the bus 41 to take in the data in the latch circuit LAT 3 will be described. As mentioned above, in a state where the latch circuit LAT3 is set to the H level, the data is transferred to the bus 41. After this, the signal LATL is set to the H level. If the data on the bus 41 has the H level, the NMOS 65 is turned on. Thereby, the latch circuit LAT 3 is discharged through the NOMOSs 64, 65 and turned to the L level.

If the bus 41 has the L level, the NOMS 65 remains in the off state. Therefore, the latch circuit LAT 3 still remains at the H level.

Thus, the transfer of the data held in the latch circuit LAT 3 to the data latch circuits 0DL-4DL enables operating the data in the data latch circuits 0DL-4DL.

(Inversion Operation of Data Held in Data Latch Circuit)

Inversion operations to inverse the data in the data latch circuits 0DL-4DL will be described. Firstly, the bus 41 is charged in accordance with the aforementioned operations, and the transfer gate 43 among any one of the data latch circuits 0DL-4DL is opened. For instance, in the case where the transfer gate 43 of the data latch circuit 0DL is opened and the node DT of the data latch circuit is H level, the bus 41 is discharged through a clocked inverter circuit of the data latch circuit 0DL, and the inversion data of a node DT is transferred to the bus 41.

Next, after the reset of the latch circuit LAT 3, the signal SET 1 is set to the L level and the node LAT of the latch circuit LAT 3 is set to the H level.

Then, if the signal LAT 1 is set to the H level, if the bus 41 is discharged by the data in the data latch circuit, the node LAT maintains the H level, and if the bus 41 sill maintains the charged state, since the NMOS 65 is turned on, the node LAT is discharged to the L level.

Next, as mentioned above, when the bus 41 is charged, and the signal BUSH 1 is turned to the H level, if the node LAT has the H level (node LATn has L level), the bus 41 maintains the H level, and if the node LAT has the L level (node LATn has H level), the bus 41 turns to the L level.

Finally, after the reset of the latch circuit LAT 2 of the data latch circuit 0DL, opening the transfer gate 43 takes the data on the bus 41 into the latch circuit LAT 2 through the transfer gate 43. As a result, if the bus 41 has the H level, the node DT turns to the L level, and if the data on the bus 41 has the L level, the node DT turns to the H level.

Summarizing the aforementioned sequence of operations, the inversion data of the node DT of the latch circuit LTA 2 is transferred to the bus 41, and the inversion data is transferred to the latch circuit LTA 1. The data in the latch circuit LTA 1 is transferred to the bus 41, and the inversion data on the bus 41 is held in the latch circuit LTA 2. In this way, the nodes DT in the data latch circuits 0DL-4DL are inversed.

The basic operations of the data control unit 3b are not limited to the aforementioned operations, and other operations can be used as the basic operations. Based on these operations, “AND”, “NAND”, “OR” logical operations may be performed on the data.

FIG. 5 shows relationships among threshold voltage distributions corresponding to each item of the writing data in the NAND flash memory and shifts of the threshold voltages due to capacitance coupling of memory cells adjacent to each other.

This embodiment shows a case in which one memory cell memorizes 2-bit data therein. The 2-bit data is simultaneously written into one memory cell. The relationships among the items of the writing data and the threshold voltages are shown by lines in FIG. 5. That is, the threshold voltages of data “11”, data “01”, data “10”, and data “00” are distributed at predetermined intervals in ascending order of threshold voltage, and one of these threshold voltages is set in each memory cell.

When storing the 2-bit data, while 4 threshold voltage distributions exist in response to the data, when storing 3-bit data in one memory, 8 threshold voltage distributions exist in response to the data, and when storing 4-bit data in one memory cell, 16 threshold voltage distributions exist in response to the data. The threshold voltage of data “11” approximately corresponds to the threshold voltage in the erasing state.

The NAND flash memory writes the data in order from the memory cells closer to the source line. Accordingly, in the next writing operation, the data is written in the memory cell connected to the word line which is closer by one to the bit line side than the word line currently selected. In terms of the features of the NAND flush memory, after the writing of the data in the memory cell connected to the selection word line, when the data is written in the memory cell connected to the next word line, the capacitance coupling of memory cells adjacent to each other and of memory cells in which the data is written previously become different from each other in response to the data to be written in the next memory cell. More specifically, the shift amount of the threshold voltages of the memory cells due to the capacitance coupling of memory cells adjacent to each other is so large when the higher side of the threshold voltage is written.

The threshold distribution indicated by a plurality of dotted lines in FIG. 5 shows an aspect of the shifts of the threshold voltages corresponding to the data to be written in the adjacent cells. As shown in FIG. 5, the higher the threshold voltage to be written in the adjacent cells, the larger the shift amounts of the threshold voltages. Therefore, when the data is read, the threshold voltage is shifted to a higher side to be read. More specifically, if the next writing data is equivalent to “11”, namely if the data is non-writing data, since the capacitance coupling of memory cells adjacent to each other depending on the next data is equal to zero, the threshold of the memory cell is read correctly. However, if the next data is other than “11”, the threshold voltage is influenced by three kinds of capacitance coupling of memory cells adjacent to each other in response to the data, and thus, the threshold voltage is read by being shifted highly more than actual threshold voltage.

### First Embodiment

FIGS. 6 to 10 show first embodiments, and show examples of writing operations based on shifts of the memory cells due to the capacitance coupling of the memory cells adjacent to each other.

In the first embodiment, as shown in FIG. 6, a present verify level is set based on the next writing data. When data “01” is written, a verify level is set to A-1, and if the data to be written in an adjacent cell (the next writing data) is “00”, a verify level A-1 is set, and if the next writing data is “10”, a verify level A-2 that is higher than the verify level A-1 is set. Further, if the next writing data is “01”, a verify level A-3 that is higher than the verify level A-2 is set, and if the next data is “11”, a verify level A-4 that is higher than the verify level A-3 is set. That is, in the next writing, the writing operation is controlled so that the threshold voltages converge with data “00” of the largest threshold voltage shift.

Referring now to FIGS. 6 to 10, writing operations will be described.

Firstly, the latch circuit LAT 1 of the sense amplifier unit 3a shown in FIG. 3 is initialized. That is, the reset signal RST is set to the H level, and the latch circuit LAT 1 is equalized. After this, the signal BLC 4 is set to the L level and the node INV is set to the H level.

Next, the writing data is sequentially loaded into the data latch circuits 1DL, 2DL from the data input output buffer shown in FIG. 4. After this, a logical “AND” computation for the data held in the data latch circuits 1DL, 2DL is performed. That is, the transfer gates 43 of the data latch circuits 1DL, 2DL are simultaneously opened. If the data in the data latch circuits 1DL, 2DL is “01”, “10” and “00”, the bus 41 changes to the L level, and if the data in the data latch circuits 0DL, 1DL is “11”, the bus 41 changes to the H level.

The level of the bus 41, as given above, is held in the latch circuit LAT 3 shown in FIG. 4. If the “AND” of the data latch circuits 1DL, 2DL has the H level (non-writing), the L level is held in the latch circuit LAT 3, and if the “AND” of the data latch circuits 1DL, 2DL has the L level (writing), the H level is held in the latch circuit LAT 3.

The data that is held in the latch circuit LAT 3 is transferred to the sense amplifier unit 3a via the bus 41. That is, firstly, the signal BUSL 2 is brought into the L level. If the node LAT of the latch circuit LAT 3 has the L level, the PMOSs 52, 53 are turned on, and the bus 41 is charged to the H level. After this, the signal BUSL 1 is set to the H level. If the node LAT of the latch circuit LAT 3 has the L level, the NMOS 68 turns on, and the NMOS 69 turns off. Thus, the bus 41 attains the H level.

If the signal BUSL 2 changes to the L level, and the node LAT of the latch circuit LAT 3 has the H level, the PMOS 52 turns on, and the PMOS 53 turns off. After this, the signal BUSL 1 attains the H level. If the node LAT of the latch circuit LAT 3 has the H level, the NMOSs 68 and 69 turn on. Thus, the bus 41 is changed to the L level.

The signal BLC 5 of the sense amplifier unit 3a is set to the H level and the level of the bus 41 is held in the latch circuit LAT 1. As a result, in the case of non-writing data, the node INV of the latch LAT 1 is set to the L level, and in the case of the writing data, the node INV of the latch circuit LAT 1 is set to the H level. After this, as mentioned above, the writing operation is executed.

During this writing operation, the data to be written in the memory cells connected to the next word line is loaded in the data latch circuits 3DL, 4DL.

As shown in FIG. 6, the verify levels are prepared by the number of items of the next writing data for the respective threshold distributions. That is, for the writing data “01”, verify levels A-1, A-2, A-3 are prepared; for the writing data “01”, verify levels B-1, B-2, B-3 are prepared; and for the writing data “00”, verify levels C-1, C-2, C-3 are prepared. These verify levels are set higher by correction values of the capacitance coupling of memory cells adjacent to each other in response to the next writing data. The threshold voltages of the memory cells are verified by using these verify levels.

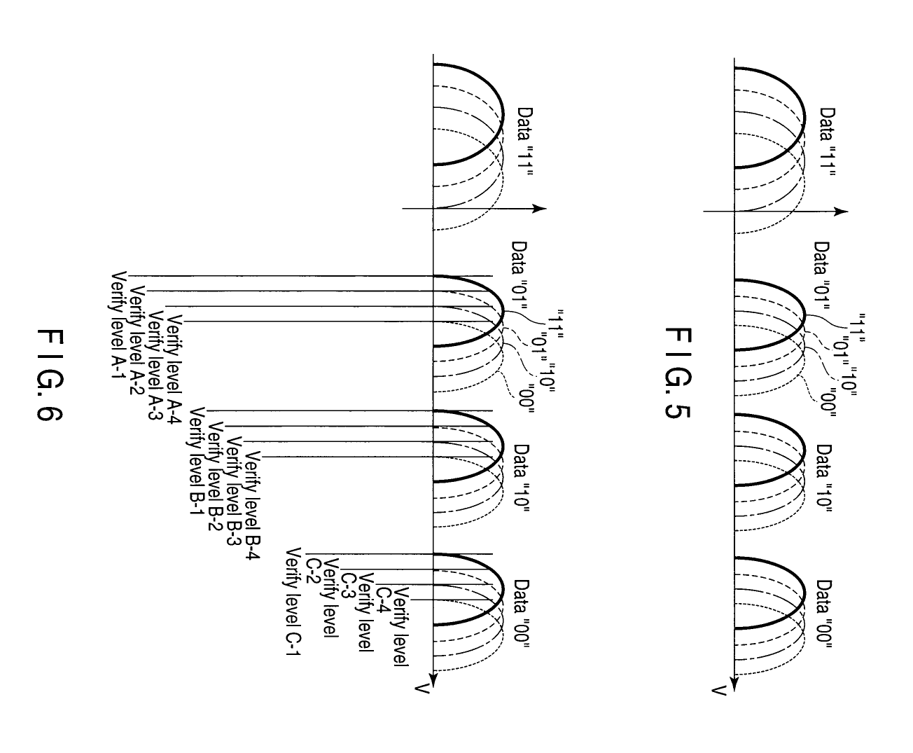

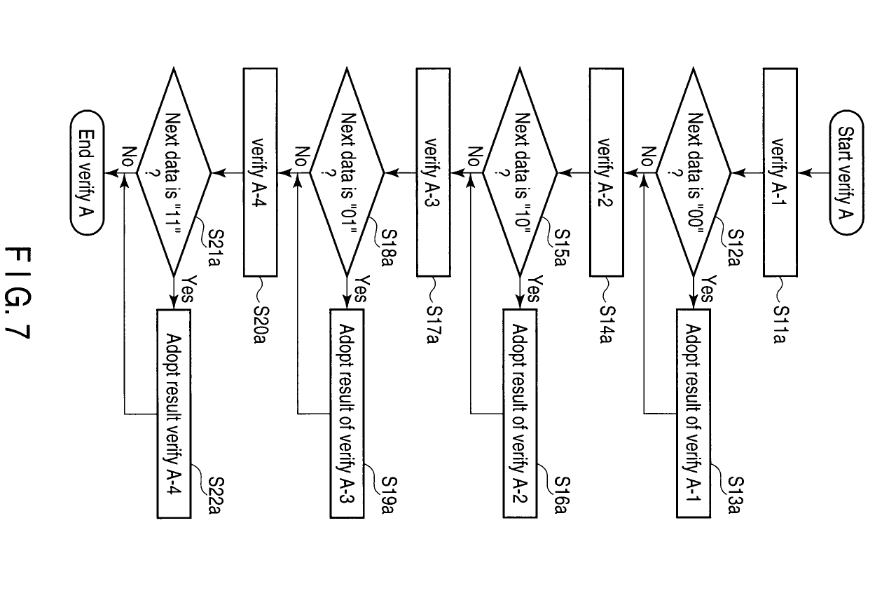

FIG. 7 shows verify operations performed on the writing data “01”, FIG. 8 shows verify operations performed on the writing data “10”, and FIG. 9 shows verify operations performed on the writing data “00”. Since these verify operations are identical, the operations will be described with reference to FIG. 7, and in FIGS. 8 and 9, the same components as those of FIG. 7 are replaced by “b”, “c” as a substitute for “a” and their explanation will be omitted.

As shown in FIG. 7, in the verify operations corresponding to the data “01”, the lowest verify level A-1 is supplied to a selected word line. As mentioned above, the verify operations are performed by using the verify level A-1 (S11a).

As a result of the verification, it is determined whether or not the writing data of the memory cell, which is connected to the next work line among an assembly having a threshold voltage which is higher than the verify level A-1, is “00”, namely, whether or not the writing data is a memory cell having the highest threshold voltage (S12a).

This determination is performed by using the data loaded in the data latch circuits 3DL, 4CL. As given above, as the verification result, in the case of “verify pass” (verification is passed), the node INV of the latch circuit LAT 1 of the sense amplifier unit 3a has the L level. In this case, for example, the next data is “00” and “verify pass” is detected by using the following condition: /3DL&/4DL&LAT1.

Here, the mark “/” indicates the inversion data, and the mark “&” indicates a logical “AND”. That is, in the case of the above condition, refers to obtaining logical AND among the inversion data in the data latch circuit 2DL, the inversion data of the data latch circuit 3DL, and the data of the latch circuit LAT1. This computation is executed by combining the basic conditions of the data control unit 3b. The computation result is held in the latch circuit Lat 3. After the operation, if the operation results in “verify pass”, the H level is held in the latch circuit LAT 3, and the L level is held in cases other than this.

Next, in the case of “verify pass” under the foregoing condition, there is no need to write the data in the memory cell. Therefore, there is a need to set non-writing data in the data latch circuits 0DL, 1DL, 2DL corresponding to the memory cell. In this case, since the non-writing data should not be set in the data latch circuits 0DL, 1DL, 2DL corresponding to the memory cell other than those of “verify pass”. Accordingly, there is a need to prepare an adequate data corresponding to the data latch circuits 0DL, 1DL, 2DL.

That is, firstly, the inversion data of the data in the data latch circuit 0DL is loaded into the bus 41. Next, the signal BUSL 1 is set to the H level. Then a discharge pass may be performed only when the node LAT of the latch circuit LAT 3 has the H level. In this case, if the node LAT has the H level, for any data, the bus 41 is set to the L level. This inversion data, namely, the L level is latched as the data. Therefore, in the data latch circuit 0DL, the data that is the “verify pass” is set.

Meanwhile, in the memory pass in which the “verify pass” has not been set yet, or the data under a condition differing from the determination condition, the discharge pass is not formed for the bus 41. Thereby, the inversion state of the data sill remains in the bus 41 as it. By inverting the remaining data to be loaded, original data is held as it is in the data latch circuit 0DL.

The foregoing operation completes an operation of (/3DL&/4DL&LAT 1)|0DL->0DL. Here, “1” indicates a logical “OR”. That is, the data of the (/3DL&/4DL&LAT 1) or of the 0DL is held in the 0DL.

In the data latch circuits 1DL, 2DL, the same operation as that of the data latch circuit 0DL is executed as follows:

(/3DL&/4DL&LAT 1)|1DL->1DL

(/3DL&/4DL&LAT 1)|2DL->2DL.

That is, the data of the (/3DL&/4DL&LAT 1) or of the 1DL is held in the 1DL, and the (/3DL&/4DL&LAT 1) or of the 2DL is held in the 2DL.

After the completion of all the operations, all the data latch circuits 0DL-2DL corresponding to the memory cells of which the verifications have been passed are set to the H level, and this completes the writing.

As the result of the determination, if the next writing data is not “00”, and if the result of the verify level A-1 has been adopted, the verify operation is executed at the verify level A-2 (S14a). That is, the verify level A-2 is supplied to the selected word line, and the verify operation is performed. After this, as in the method given above, it is determined whether or not the next writing data is “10” (S15a), and in the case of “10”, the result of the verify level A-2 is adopted (S16a).

That is, operations are performed as follows:

(3DL&/4DL&LAT 1)|0DL->0DL

(3DL&/4DL&LAT 1)|1DL->1DL

(3DL&/4DL&LAT 1)|2DL->2DL.

As a result, all the data latch circuits 0DL-2DL corresponding to the memory cells that are the “verify pass” are set to the H level.

Meanwhile, in memory cells which have not passed the “verify pass”, or in the data differing from the determination condition, the discharge path is not formed for the bus 41. Therefore, the inversion state of the data remains as it is on the bus 41. Inverting to load this data leaves the original data as it is in the data latch circuits 0DL-2DL.

Hereinafter, in a similar way, the verify operations using the verify levels A-3, A-4, and the operations corresponding to the next writing data “01”, “11” are executed (S17a-S22a).

As the result of the determination, if the next writing data is not “10”, and if the result of the verify level A-2 is adopted, the operation of the verify level A-3 is performed (S17a). That is, the verify level A-3 is supplied to the selected word line, and the verify operation is performed.

After this, it is determined whether or not the next writing data is “01” (S18a). As a result, if the next writing data is “01”, the verify result at the verify level A-3 is adopted (S19a).

As the result of the aforementioned determination, if the next writing is not “01”, and if the result of the verify level A-3, the verify operation at the verify level A-4 is executed (S20a). That is, the verify level A-4 is supplied to the selected word line and the verify operation is performed.

After this, it is determined whether or not the next writing data is “11” (S21a). As a result, if the next data is “11”, the verify result of the verify level A-4 is adopted (S22a).

As given above, the verify operations at the verify level A are completed.

Next, in the same way as that of the verify level A, a verify operation at a verify level B shown in FIG. 8 is performed, and after this, a verify operation at a verify level C shown in FIG. 9 is executed.

As the result of the verify operations using each verify level A, B, and C, if the verification is not passed, a program voltage is increased slightly, and a writing operation is performed again. Then, the verify operations using each verify level A, B, C are executed. Such an operation will be repeated until all the selected memory cells become “verify pass”.

According to the first embodiment, in the verify operation in which the next writing data is loaded into the data latch circuits 2DL, 3DL, and the verify level corresponding to the next wiring data is used during writing operation, if the verification result agrees with the next writing data, the verification is passed and the verification result is adopted. In this way, if the data to be written next corresponds to a high threshold voltage, it is considered that the shift due to the capacitance of the coupling of memory cells adjacent to each other is inevitably large. Thereby, the data is verified at a lower verify level, and the thresholds are written at lower levels in descending order of the capacitances of the coupling of the memory cells adjacent to each other. Thus, the threshold voltage of the shift due to the writing of the data in the memory cells selected by the next word line may be cancelled in advance.

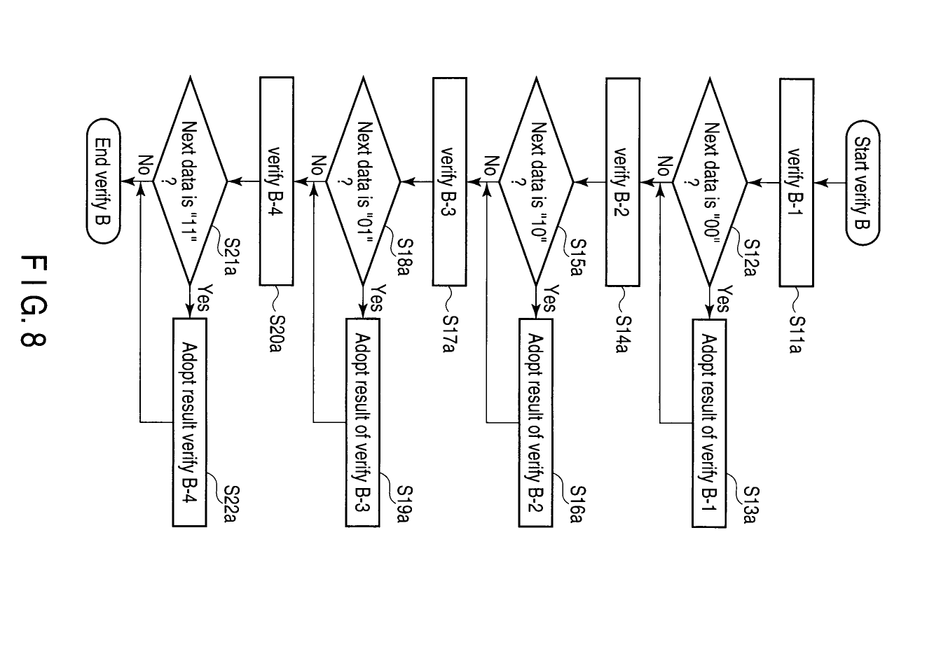

FIG. 10 shows a threshold voltage distribution after the compensation of the capacitance coupling regarding the first embodiment. In each verify level shown by a dotted line, adjusting each threshold voltage distribution corresponding to the next writing data enables to avoid the dependency of the capacitance coupling due to the next writing data. Therefore, regardless of the next writing data, the threshold voltage distribution of each data can be adjusted to each verify level indicated by the dotted line. Thus, in the reading of the data “01”, “10”, “11”, the threshold voltage distribution corresponding to each data can be adjusted to each reading level margin. Thus, erroneous reading may be prevented.

### Second Embodiment

FIGS. 11 to 14 show second embodiments, respectively. The second embodiment is an example of a method for reducing the number of times of verifications in comparison with the first embodiment to shorten a program time. In FIGS. 11 to 14, the same components as those of the first embodiment are designated by identical symbols, and solely the different components will be explained.

The verify method in the first embodiment verifies all data to be written in the memory cells connected to the next word line. According to this verification, since the number of times of verifications required is equal to the number of the data to be written next, the verify method is not a practical one because the program and the verify time become long.

Therefore, in the second embodiment, the verify time may be reduced by verifying pairs having large extents of the capacitance of the coupling of the memory cells adjacent to each other together among the data to be written in the memory cells connected to the next word line. That is, in the data to be written to the memory cells connected to the next word line, changes of the threshold voltages corresponding to the pair of the data “11”, “01” and the pair of the data “10”, “00” are close to each other. Accordingly, the verify level corresponding to each of data is set to verify on the basis of each pair of data.

More specifically, as shown in FIG. 11, in a case of bit assignment in the second embodiment, the pair of “11”, “01”, and the pair of “10”, “00”, lower bit data may be separated into “1” and “0”. Therefore, in the second embodiment, for example, in the case of writing of the data “01”, the verify method firstly verifies the data “01” by using a verify level A-1, and verifies the data “01” by using the verify level A-3. In the case of writing of the data “10”, the method firstly verifies the data “10” by using the verify level B-1, and verifies the data “10” by using the verify level B-3. Further, in the case of writing of the data “00”, the method firstly verifies the data “00” by using the verify level C-1, and verifies the data “00” by using the verify level C-3.

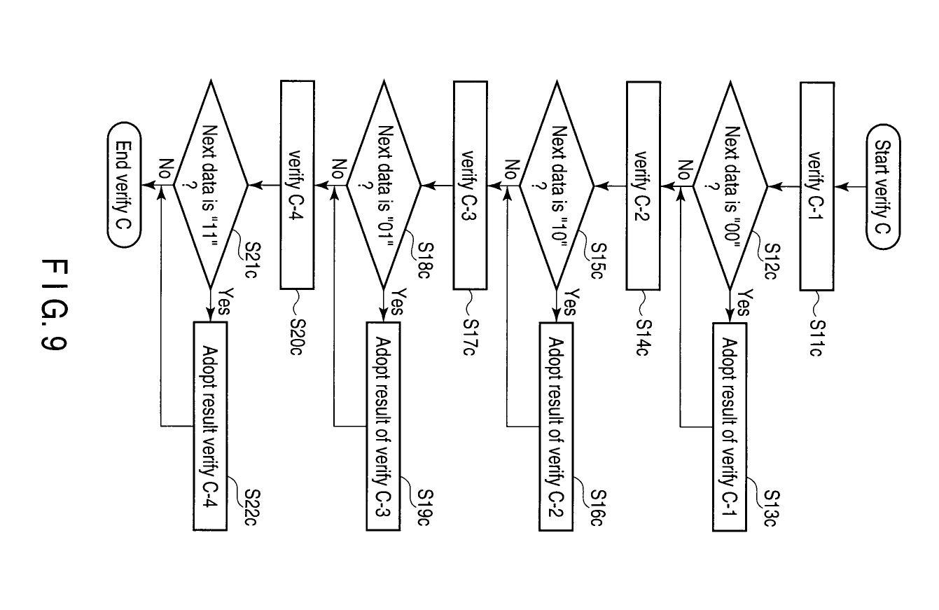

FIGS. 12 to 14 each show verify operations regarding the second embodiment. In the second embodiment, as is similarly shown in the first embodiment, the data, to be written in a memory cell connected to a next word line, that is affected more by adjacent memory cell capacity coupling is written in a lower level.

As shown in FIGS. 11 and 12, in the verify operations according to the data “01”, the verify level A-1 with the lowest level is supplied to the selected word line. As mentioned above, the verify operation is executed by using this verify level A-1 (S11a).

As the result of the verification, the lower bit of the writing data of the memory cell connected to the next word line in a set having a threshold voltage higher than the verify level A-1 is distinguished by aforementioned operation whether it is “0” or not (S31a).

In the case of the “verify pass” under the given condition, there is no need to write the data in those memory cells. Therefore, the non-writing data is set to the data latch circuits 0D1, 1DL, 2DL corresponding to these memory cells.

Meanwhile, in the case of the memory cells which have not performed the “verify pass”, or in the case of the data under the determination condition, the original data is held as it is in the data latch circuits 0DL, 1DL, 2DL.

As the result of the given determination, if the lower bit of the next writing data is not “0”, and if the result of the verify level A-1 is adopted, the verify operation at the verify level A-3 is performed (S17a). That is, the verify level A-3 is supplied to the selection word line, and the verify operation is performed. After this, as described above, it is determined whether or not the lower bit of the next writing data is set to “1” (S32a), and if the lower bit is set to “1”, the result of the verify level A-3 is adopted (S19a).

In the case of the “verify pass” under the given condition, there is no need to write the data in those memory cells. Therefore, the non-writing data is set to the data latch circuits 0DL, 1DL, 2DL corresponding to these memory cells.

Meanwhile, in the case of the memory cells which have not performed the “verify pass” yet, or in the case of the data under a different determination condition, the original data is held as it is in the data latch circuits 0D1, 1DL, 2DL.

As mentioned above, the verify operations at the verify level A are completed.

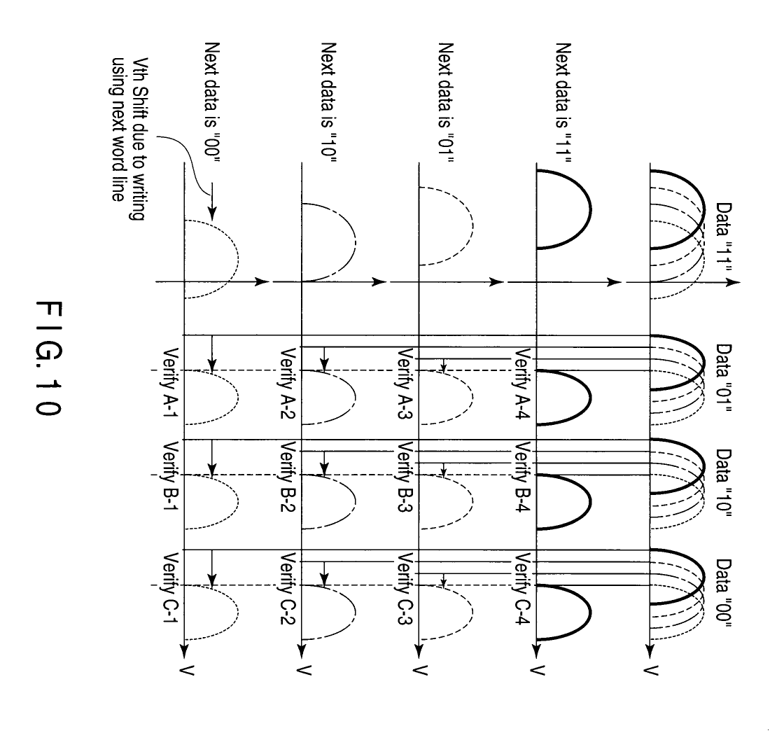

Next, in the same way as that of the verify level A, the verify operations at the verify level B shown in FIG. 13 is performed, and after this, the verify operations at the verify level C shown in FIG. 14 are executed.

According to the second embodiment, the verify level can be decreased in comparison with the first embodiment. Therefore, the verify time may be shortened, and the writing at a speed which is faster than that of the first embodiment may be performed.

### Third Embodiment

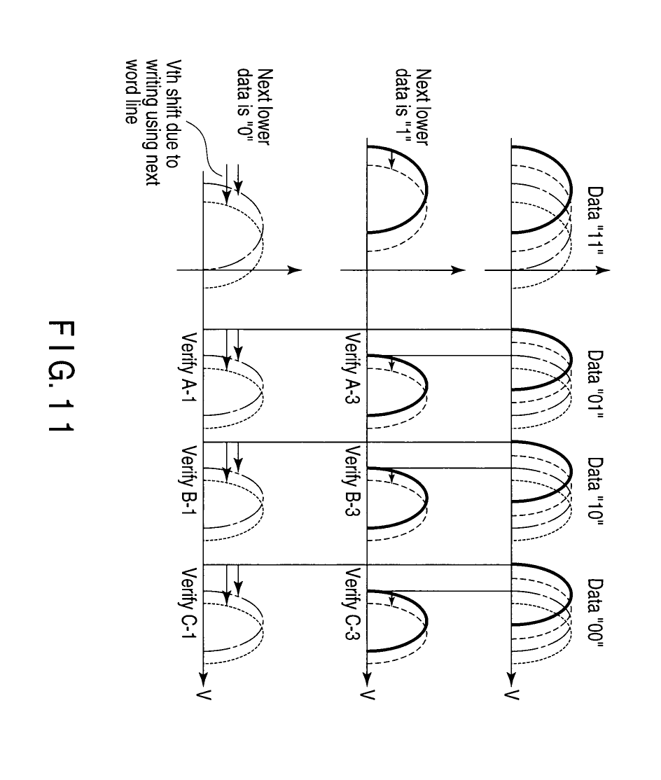

FIGS. 15 to 21 each show third embodiments. The third embodiment relates to a compensation method for the capacitance coupling of the memory cells adjacent to each other configured to write at a speed which is faster than that of the second embodiment.

In the third embodiment, as mentioned in the first and second embodiments, the compensation method does not set a plurality of verify levels corresponding to the writing data “01”, “10”, “00”, respectively, but sets a single verify level corresponding to each writing data “01”, “01”, “00”. After the verify operation based on the foregoing verify level, the aforementioned coupling capacitance may be compensated by converting an extent of the coupling capacitance of the memory cells adjacent to each other due to the data to write in the memory cells connected to the next word line into a concept of “the remaining number of times of applications of the program voltages”, namely “the remaining number of times of writing”.

For instance, as shown in FIG. 15, if the writing data in the memory cells connected to the next word line is “11”, the threshold voltage is not shifted; if the next writing data is “01”, the threshold voltage of one time of the program is shifted; if the next writing data is “10”, the threshold voltage of two times of programming is shifted; and if the next writing data is “00”, the threshold voltage of three times of programming is shifted.

In these cases, if the writing data in the memory cells connected to the next word line is “11”, the remaining number of times of programming (writing) after the verification is set to three times; if the next writing data is “01”, the remaining number of times of programming is set to two times; if the next writing data is set to “10”, the number of the remaining times of programming is set to one time; and if the next writing data is set to “00”, the remaining number of times of programming is set to “0” times. In this way, controlling the remaining number of times of writing enables compensating a shift amount of the threshold voltage corresponding to each capacitance coupling.

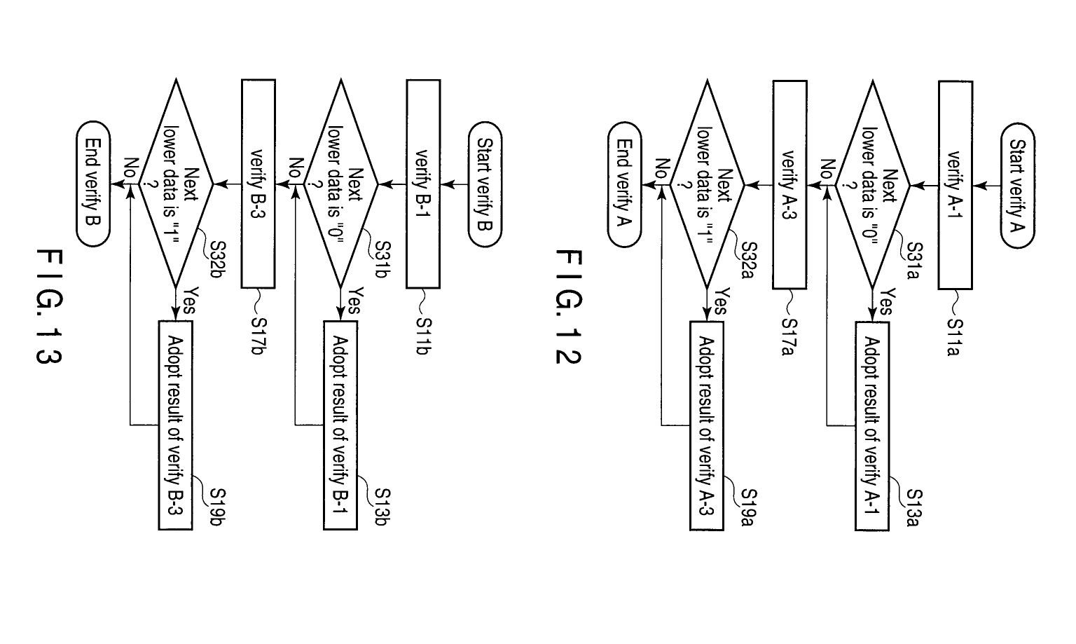

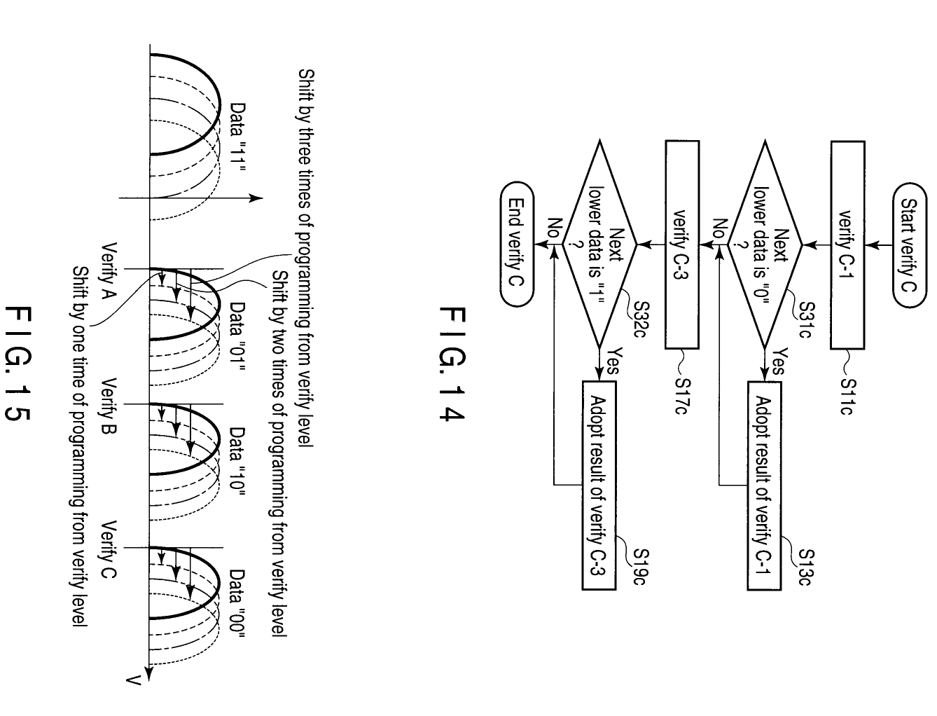

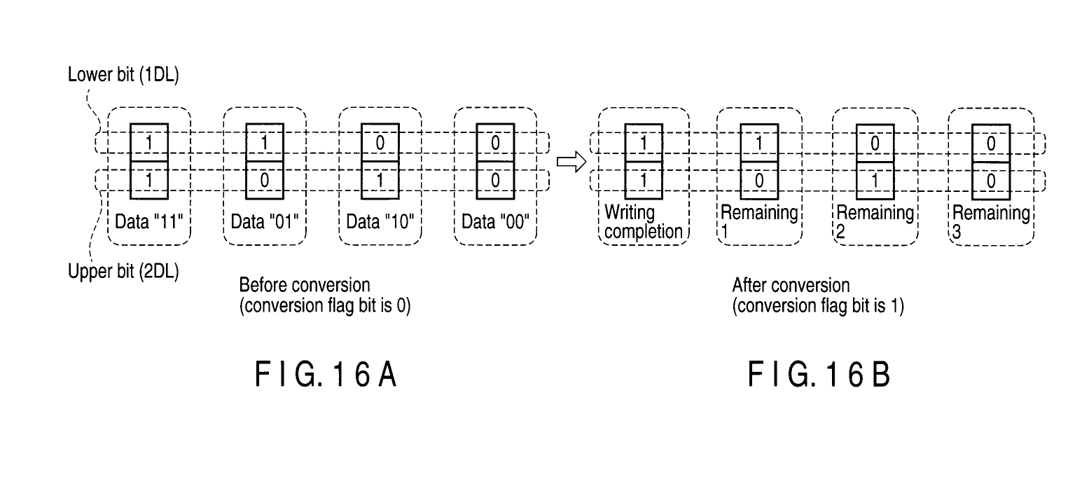

FIGS. 16A and 16B show changes in meaning of the data with data conversion operations. FIG. 16A shows writing data before conversion held in the data latch circuits 1D1, 2DL, and FIG. 16B shows data of the number of times of programming after conversion held in the data latch circuits 1DL, 2DL. After the conversion, the data “11” in the data latch circuits 2DL, 2DL shows the writing completion; the data “10” in the data latch circuits 1DL, 2DL shows one time of the remaining number of times of programming; the data “01” in the data latch circuits 1DL, 2DL shows two times of the remaining number of times of programming; and the data “00” in the data latch circuits 1DL, 2DL shows three times of the remaining number of times of programming.

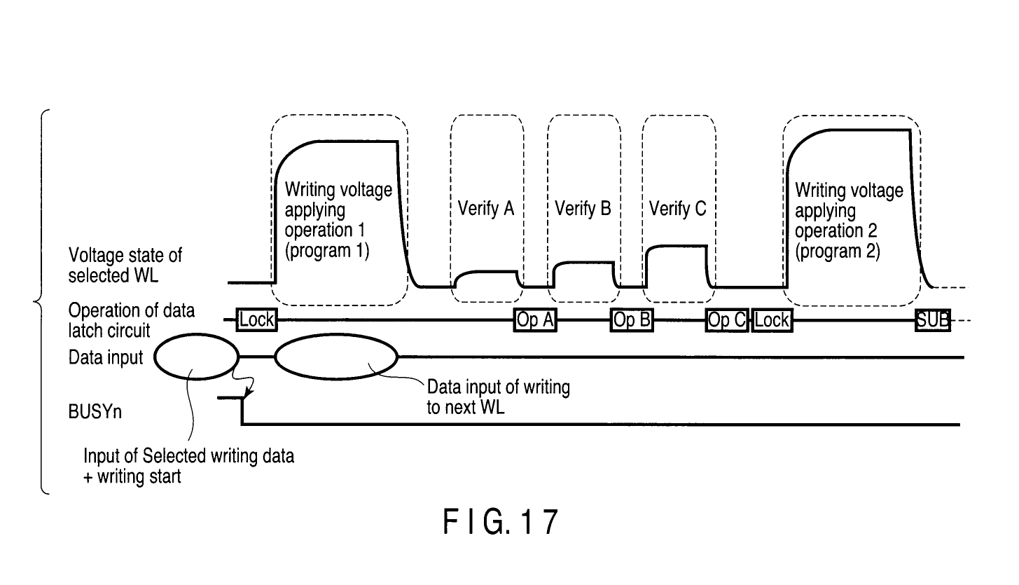

FIG. 17 shows an example of a writing sequence of the third embodiment. Referring now to FIG. 17, the writing sequence of the third embodiment will be schematically described.

Firstly, the writing data is loaded into the data latch circuits 1DL, 2DL. After this, in a Lock period, the data latch circuit 0DL is set to the data “0” showing a non-writing state, the data held in the data latch circuits 1D1, 2DL is operated as mentioned above, and set to the sense amplifier unit 3a. Next, a writing voltage (program voltage) is applied to the selection word line, and a first program operation is executed. In a period of the writing operation, the writing data for the memory cells connected to the next word line is loaded into the data latch circuits 3DL, 4DL.

After the completion of the writing, the verify operation is performed at the verify level A (Verify A). Next, in a period of an Op A, the writing data in the data latch circuits 1DL, 2DL is converted into the remaining number of times of the writing on the basis of the next writing data held in the data latch circuits 3DL, 4DL.

After this, a verify operation (Verify B) is performed at the verify level B. Next, in a period of an Op B, the writing data in the data latch circuits 1D1, 2DL is converted into the remaining number of times on the basis of the next writing data held in the data latch circuits 3D1, 4DL.

Further, a verify operation (Verify C) is performed at the verify level C. Next, in a period of an Op C, the writing data in the data latch circuits 1DL, 2DL is converted into the remaining number of times of writing on the basis of the next writing data held in the data latch circuits 3DL, 4DL.

In this way, after conversion of the data in the data latch circuits 1DL, 2DL into the remaining number of times of writing, in a Lock period, the data in the data latch circuits 1DL, 2DL is set in the sense amplifier.

After this, a writing voltage is applied to the selection word line, and a second program operation (program 2) is executed. After this, in a subtraction (SUB) period, “1” is subtracted from the remaining number of times of writing in the data latch circuits 1DL, 2DL. Next, the data in the data latch circuits 1DL, 2DL is set in the sense amplifier unit, a third program operation (not shown) is executed. In this way, upon every execution of the program operation, “1” is subtracted from the data of the remaining number of times of writing in the data latch circuits 1D1, 2DL. This operation will be repeated until the data in all the data latch circuits 1DL, 2DL becomes “11”.

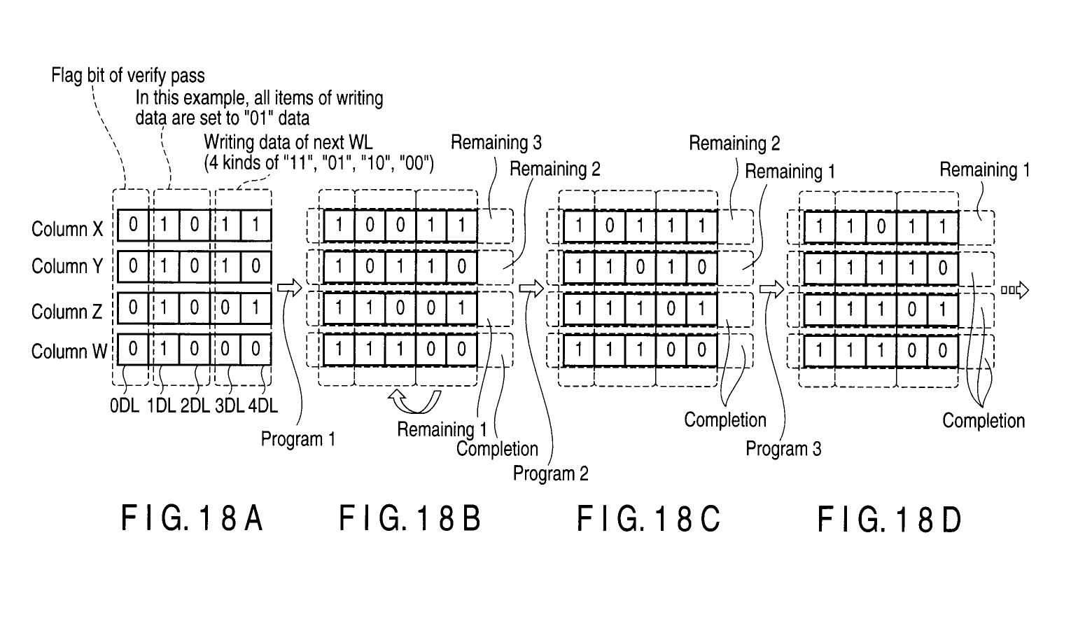

Next, operations of the third embodiment will further described with reference to FIGS. 18 to 21.

FIG. 18 shows an aspect of a change in data in the data latch circuits 0DL-4DL with the foregoing program and the verify operations. FIG. 18 shows an example of four columns, X, Y, Z, and W. Here, it is assumed that the data latch circuit 0DL holds a flag for data conversion. It is assumed that an upper bit of the writing data is held in the data latch circuit 2DL and a lower bit is held in the data latch circuit 1DL. It is assumed that an upper bit of the next writing data is held in the data latch circuit 4DL, and a lower bit of the next data is held in the data latch circuit 3DL.

FIG. 18A shows the content of each data latch circuit before programming. In FIG. 18A, all items of the writing data in each column are “01”, and the next writing data is set to “11”, “10”, “01”, “00” in response to columns X, Y, Z and W. In this state, as mentioned above, the first program operation (program 1) is executed, verify operations at the verify levels A, B, C and data conversion operations are performed.

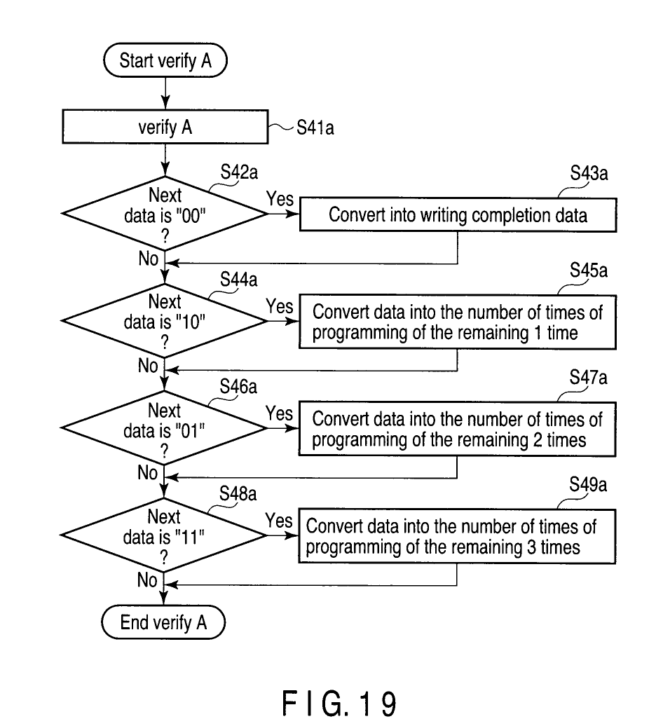

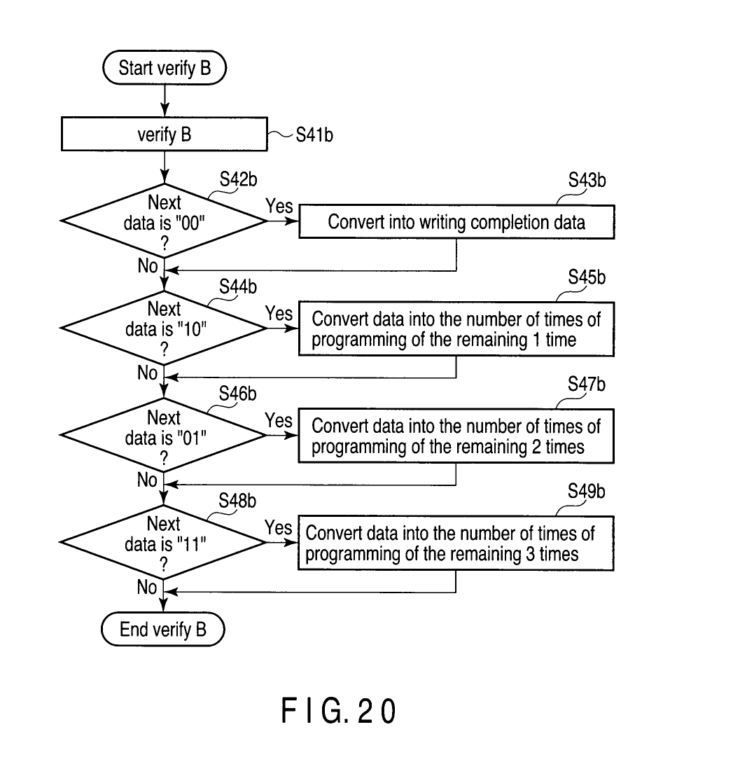

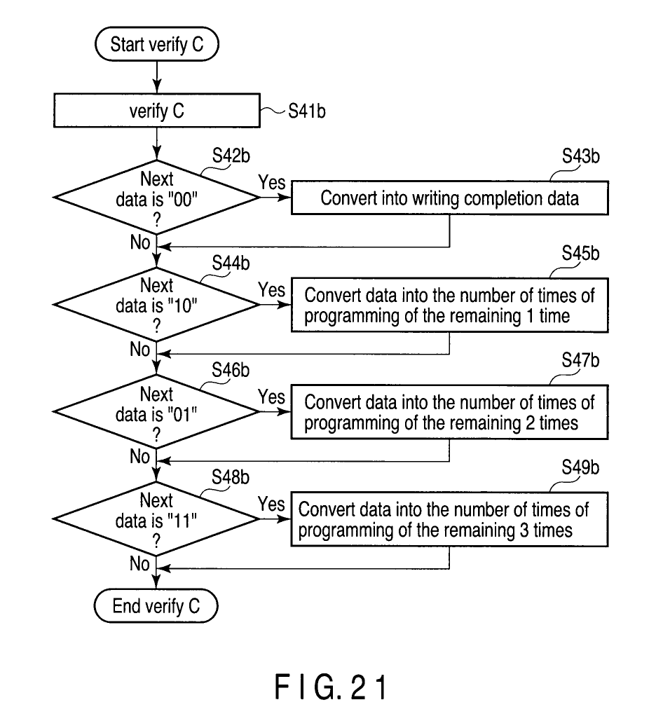

FIG. 19 shows verify operations and data conversion operations at the verify level A, FIG. 20 shows verify operations and data conversion operations at the verify level B, and FIG. 21 shows verify operations and data conversion operations at the verify level C. In FIGS. 19 to 21, the same operation components are indicated by adding suffixes “a”, “b”, “c” to each of the identical symbols. Here, operations at the verify level A shown in FIG. 19 will be concretely described.

After the completion of the operation of the first program, the verify operation at the verify level A is executed (S41a). When the verify operation is completed, the data in all the data latch circuits 0DL is set to “1” as shown in FIG. 18B.

Next, it is determined whether or not the next writing data is “00” for the assembly having the threshold voltage which is higher than the verify level A (S42a). As a result, if the next writing data is “00”, the writing data held in the data latch circuits 1DL, 2DL is converted into writing completion data (S43a). That is, the data in the data latch circuits 3DL, 4DL is inverted to be latched in the data latch circuit 1DL, 2DL, respectively. More specifically, if the next data is “00”, as in the column W, the data “00” is inverted to be latched as the data “11” in the data latch circuits 1DL, 2DL. Since the data “11” has the remaining number of times of programming of 0 times, the resulting writing data is converted into the completion of the writing data (S43a).

If the next writing data is “10” (S44a), the data “10” is inversed to be latched as the data “01” in the data latch circuits 1DL, 2DL. Thereby, the resulting writing data is converted into the data showing the remaining number of times of programming of one time (S45a).

If the next data is “01” (46a), the data “01” is inverted to be latched as the data “10” in the data latch circuits 1D1, 2DL (S47a).

If the next data is “11” (S48a), the data “11” is inverted to be latched as the data “00” in the data latch circuits 1DL, 2DL. Thereby, the next data results in conversion into the data showing that the remaining number of times of programming is three times (S49a).

Next, verify operations based on the verify level B show in FIG. 20 are performed in the same way as that of the verify level A, and after this, data conversion operations are executed. Next, verify operations based on the verify level C shown in FIG. 21 are performed in the same way as that of the verify level A, and after this, data conversion operations are executed.

After the completion of the data conversion operations as mentioned above, the second program (program 2) is performed on the basis of the converted data in the data latch circuits 1DL and 2DL as shown in FIG. 18B. After this, as shown in FIG. 18C, “1” is subtracted from the remaining number of times of the writing data in each data latch circuit 1DL, 2DL. These subtraction operations may be achieved by inverting the next writing data, for example, held in the data latch circuits 3DL, 4DL to obtain a logical AND between the data in the data latch circuits 1DL, 2DL.

In this way, after the remaining number of times of writing is updated, a third program operation (program 3) is executed. After this, as shown in FIG. 18D, “1” is subtracted from the remaining number of times of the writing data in each data latch circuit 1DL, 2DL.

As given above, every time the writing operation is performed, the operations are repeated until the remaining number of times of writing is subtracted, and the data in all the data latch circuits 1DL, 2DL reach “11”.

According to the third embodiment, the compensation method verifies operations by using three verify levels corresponding to the writing data “01”, “10”, “00”, respectively, converts the extent of the coupling capacitance of memory cells adjacent to each other into the remaining number of times of writing (the number of times of applications of writing voltages), subtracts this remaining number of the times of writing after the program operation, and controls the program and verify operations. Therefore, in comparison with the first and the second embodiments, the method may further reduce the verify level, and reduce the number of verify times. Thus, the compensation method can achieve speed-up of the writing speed.

While the third embodiment has set the remaining number of times of programming in integral multiples such as one time, two times and three times, the invention is not limited to this embodiment; it is also able to set the remaining number of times of programming to a small multiple, for example, by controlling the voltage of a bit line for writing the data. In this way, by setting the number of times to a small multiple, a further precise programming is enabled. A concrete example will be described later.

### Fourth Embodiment

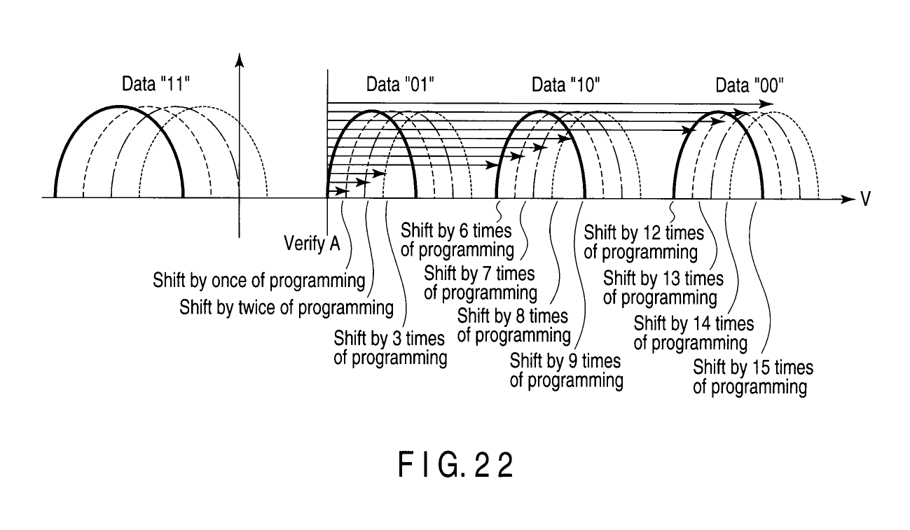

FIG. 22 shows a fourth embodiment. The fourth embodiment is made by modifying the third embodiment. The third embodiment verifies the writing data “01”, “10”, “00” by using three verify levels corresponding to the foregoing writing data, respectively. Meanwhile, the fourth embodiment verifies the three items of writing data “01”, “10”, “00” by setting one verify level to the foregoing three items of data, respectively, and after this, converts the remaining number of times of writing data on the basis of the writing data and the next writing data.

That is, as shown in FIG. 22, one verify level A is set to the three items of the writing data “01”, “10”, “00”, and the threshold voltages corresponding to the three items of the writing data “01”, “10”, “00” are verified by using the verify level A. FIG. 22 shows the shift of the threshold voltages through the number of times of programming if the next writing data is “11”, “01”, “10”, and “00” for, the writing data “01”, “10”, “00”.

In other words, in the writing data “01”, it is assumed that if the next data is “11”, the threshold voltage is shifted by 0 times of the number of times of programming; if the next writing data is “01”, the threshold voltage is shifted by one time of the number of times of programming; if the next writing data is “10”, the threshold voltage is shifted by two times of the number of times of programming; and if the next writing data is “00”; the threshold voltage is shifted by three times of the number of times of programming.

In the writing data “10”, it is assumed that if the next writing data is “11”, the threshold voltage shifts by 6 times of the number of times of programming; if the next writing data is “01”, the threshold voltage shifts by 7 times of the number of times of programming, if the next writing number is “10”, the threshold shifts by 8 times of the number of times of programming; and if the next writing data is “00”, the threshold voltage shifts by 9 times of the number of times of programming.

In the writing data “00”, it is assumed that if the next writing data is “11”, the threshold voltage shifts by 12 times of the number of times of programming; if the next writing data is “01”, the threshold voltage shifts by 13 times of the number of times of programming; if the next writing number is “10”, the threshold shifts by 14 times of the number of times of programming; and if the next writing data is “00”; the threshold voltage shifts by 15 times of the number of times of programming.

Based on the given assumption, the writing data and the next writing data is converted into the remaining number of times of writing on the basis of the writing data and the next writing data.

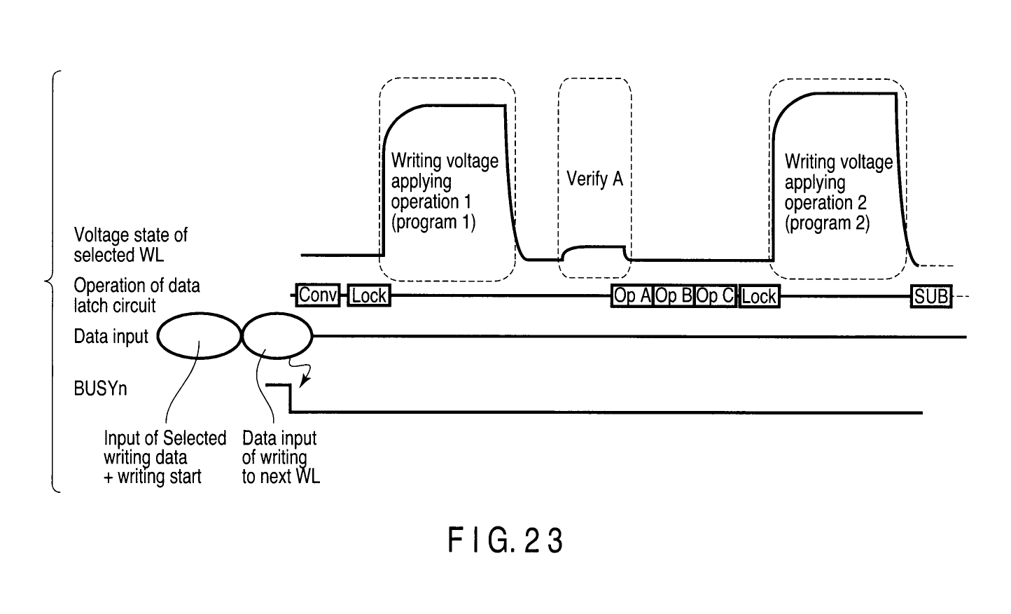

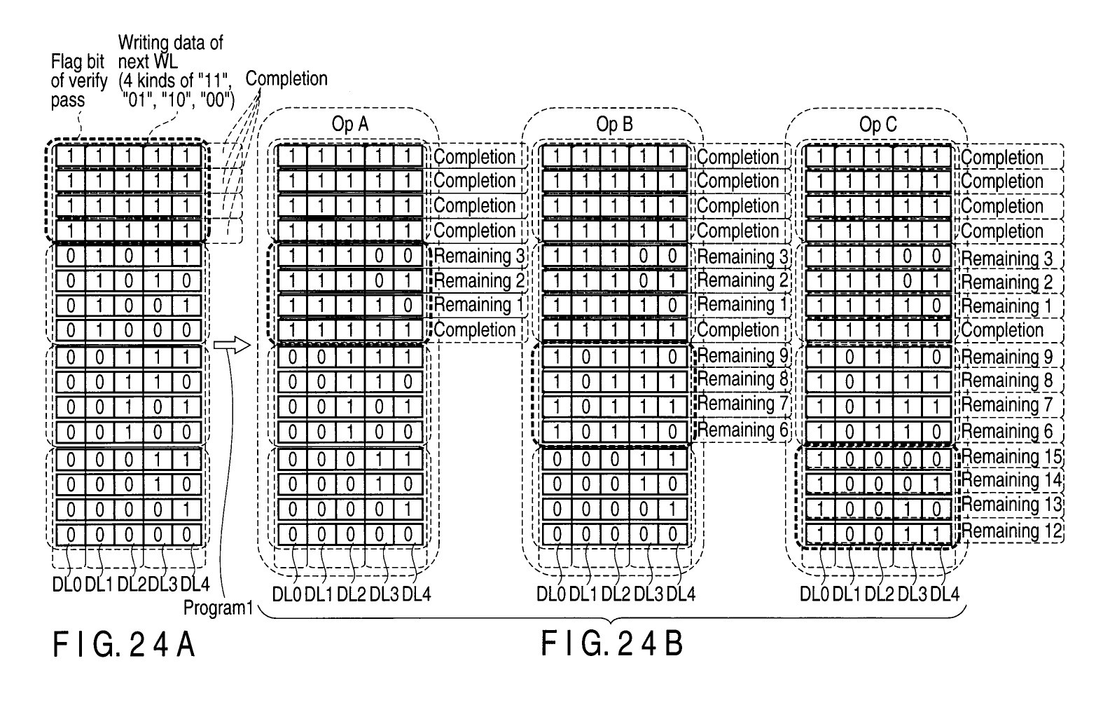

FIG. 23 shows an example of a writing sequence of the fourth embodiment, and FIG. 24 shows an example of a data conversion operation.

In the fourth embodiment, in the case of non-writing data, all the data latch circuits 0DL-4DL are reset to “1”. Therefore, there is a need for the writing data and the next writing data to be loaded in the data latch circuits 1DL-4DL. An operation to perform this data loading and to reset all the data latch circuits 0DL-4DL corresponding to the case of the non-writing data is executed in a “Cony” period before the “Lock” period.

FIG. 24A shows the data latch circuits 0DL-4DL after the “Cony” period. If the data in the data latch circuits 1DL, 2DL is “11”, and if the data in the data latch circuits 3DL, 4DL is “11”, namely, in the case of non-writing data, the data in the data latch circuit 0DL is set to “1” indicating the “verify pass”. The writing data and the next writing data are stored in the other data latch circuits 0DL-4DL.

After this, in the “Lock” period, the writing data in the data latch circuits 1DL, 2DL are set in the sense amplifier unit. Next, a program voltage is applied to the selected word line to execute the first program operation (program 1).

Next, the verify operation is executed at the verify level A. As the result of the verify operation, the data in the memory cells which have passed the verification are converted into the remaining number of times of writing (the remaining number of times of writing voltage applying operations) on the basis of the next writing data.

That is, as shown in FIG. 24B, firstly, at the Op A, the writing data “01” is converted, next, at the Op B, the writing data “10” is converted, and finally, at the Op C, the writing data “00” is converted. As a result, as shown at the Op C, the remaining number of times of writing is set to the data latch circuits 1DL, 2DL, 3DL, 4DL on the basis of the data held in the data latch circuits 1DL, 2DL and of the data held in the data latch circuits 3D1, 4DL. Namely, the remaining number of times of writing of 15 times is indicated by the 4-bit data.

In this way, after execution of the data conversion operation, in the “Lock” period, the data latch circuits 1DL, 2DL are set to the sense amplifier unit 3a, and the second program operation (program 2) is executed.

After the operations of the second program, in the SUB period, “1” is subtracted from the remaining number of times of the writing. These program operations and the subtraction operations are repeated until the data in all the data latch circuits 0DL-4DL become “1”.

According to the fourth embodiment, the verify level is set to a single verify level. Therefore, the verify time may be reduced, and the writing speed may be speeded up.

### Fifth Embodiment

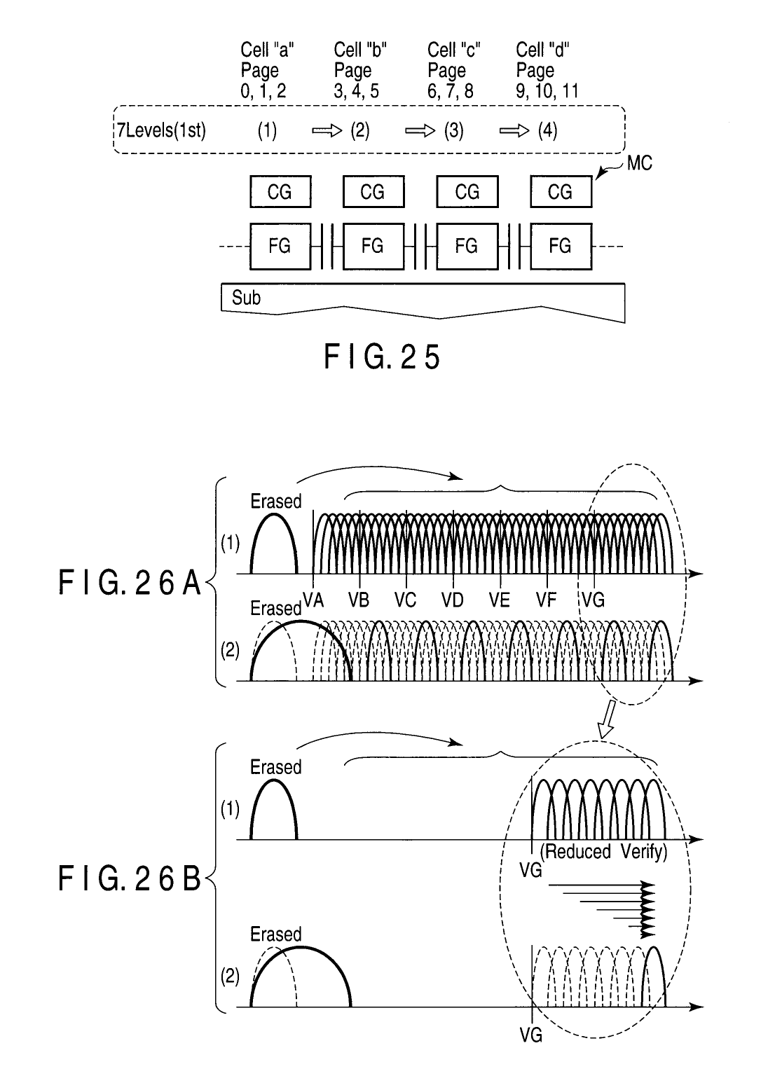

FIGS. 25, 26 and 27 show a fifth embodiment. The fifth embodiment is an example of a modification of the third example. The third embodiment has described the case in which 2-bit data is written in a single memory cell. However, the fifth embodiment shows the case in which 3-bit data is written in a single cell.

FIG. 25 shows writing order of data in memory cells “a”, “b”, “c”, “d” each connected to adjacent and different word lines.

As shown in FIG. 25, in the case of the fifth embodiment, (1): 3-bit data is written in the memory cell “a”. Then, (2): 3-bit data is written in the memory cell “b” connected to the next word line. Next, (3): 3-bit data is written in the memory cell “c” connected to the next word line. After this, (4): 3-bit data is written in the memory cell “d” connected to the next word line.

In FIG. 26A, (1) shows a threshold voltage distribution in the case where the 3-bit data is written in the memory cell “a”. VA, VB-VG each indicate the verify levels.

In FIGS. 26A and 26B, (2) shows a threshold voltage distribution of the memory cell “a” in the case where the 3-bit data is written in the memory cell “b” connected to the next word line. In this way, the threshold voltage distribution of the memory cell “a” is distributed in an original level due to the capacitance coupling by writing the data in the memory cell “b” connected to the next word line.

FIG. 26B is a figure in which a part of FIG. 26A is expanded.

In the case of the fifth embodiment, to hold 8-value data, seven data latch circuits are needed. The 3-bit data are simultaneously written, the remaining number of times of writing is set to 7 times at a maximum by means of the data conversion operation, and writing operations are executed.

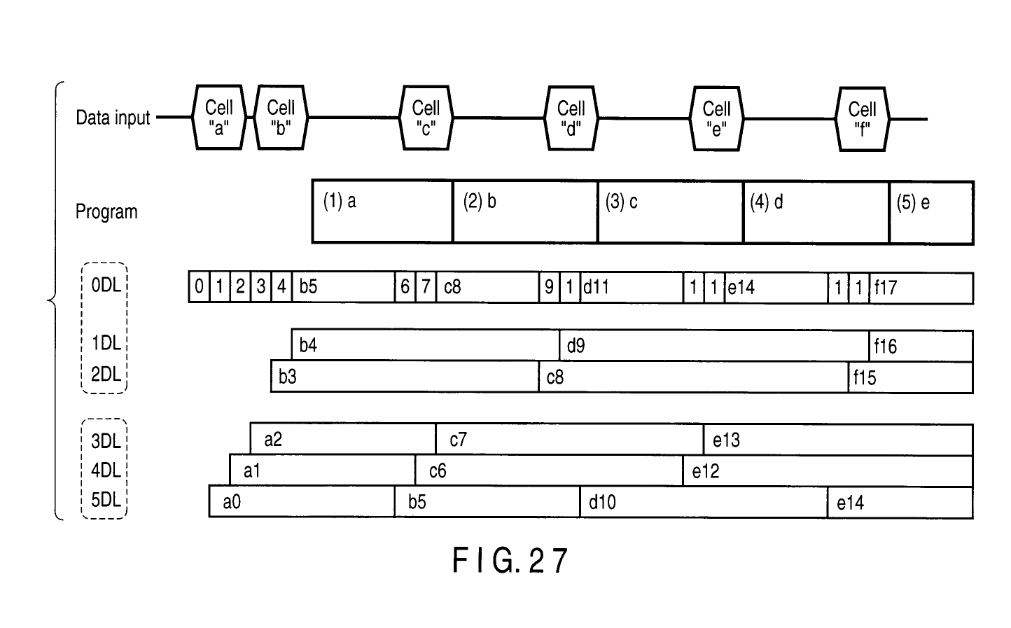

FIG. 27 shows the data writing order of the fifth embodiment, and the same components as those of FIG. 25 are designated by identical symbols. FIG. 27 shows a transition of order of writing data, and the numbers, for example, “0”-“b5”-“e14” corresponding to the data latch circuits 0DL to 5DL each mean page numbers shown in FIG. 25, and letters such as “a”, “b”, “c” refer to each cell. For instance, the data “a0” stored at the top of the data latch circuit 5DL means a least significant bit (page zero), and the data “a1” means the next bit (page one) of the cell “a”.

In this way, the threshold voltage distribution of each of writing data is arranged with the maximum capacitance coupling. For this reason, the threshold voltage distribution can be set at the original voltage level by writing the data in the memory cells connected to the next word line.

According to fifth embodiment, 3-bit data may be written precisely while compensating the coupling capacitance of memory cells adjacent to each other.

### Sixth Embodiment

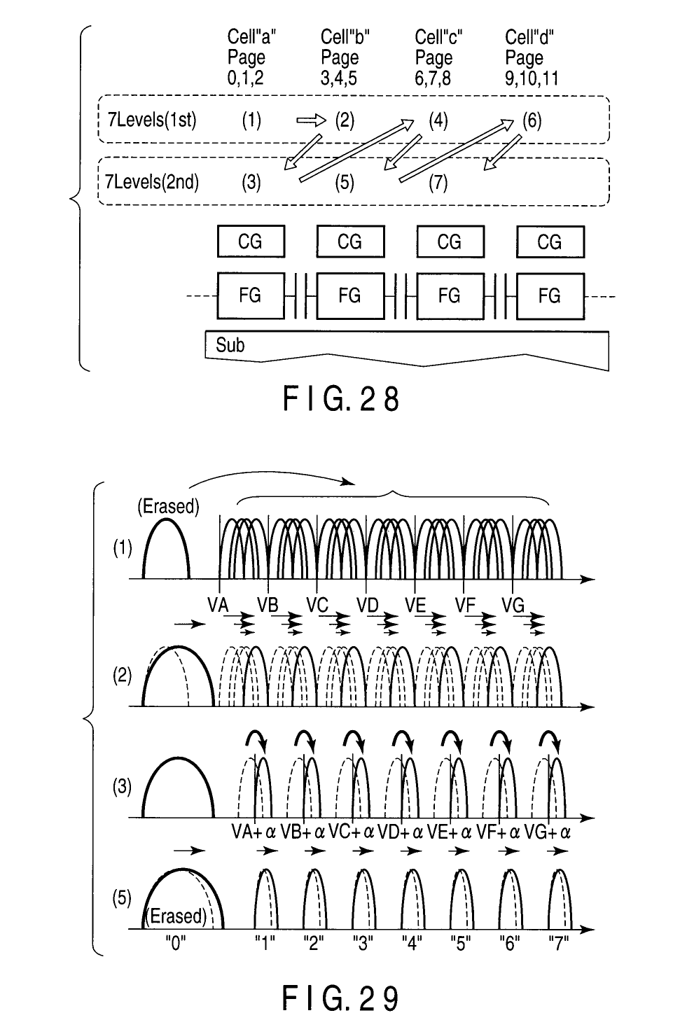

FIGS. 28, 29 show a sixth embodiment. The sixth embodiment is a modification of the fifth embodiment. The fifth embodiment writes 3-bit data at one time in the memory cells by sequentially selecting the word lines adjacent to each other.

Meanwhile, the sixth embodiment writes 3-bit data in a single memory cell separately twice as shown in FIG. 28. That is, firstly in (1), 3-bit data is written in the memory cell “a”. After this, in (2), 3-bit data is written in the memory cell “b” connected to the next word line. Next, in (3), the 3-bit data is written again in the memory cell “a”. Then, in (4), 3-bit data is written in the memory cell “c” connected to the word line distant by two from the word line to which the memory cell “a” is connected. After this, in (5), 3-bit data is written in the memory cell “b” connected to the word line adjacent to the word line to which the memory cell “a” is connected.

FIG. 29 shows a change in threshold voltage distribution of the memory cell “a”. In (1), firstly, 3-bit data is written in the memory cell “a”. While in the fifth embodiment, the remaining number of times of writing is set to 7 times as a maximum, in the sixth embodiment, the remaining number of times is set 3 times at a maximum. Then, the remaining writing operations are executed, and a threshold voltage is set at a rough level.

In (2), when the memory cell “b” is written, the threshold voltage distribution shifts due to capacitance coupling.

After this, in (3), the writing operations are executed again through the 3-bit data to the memory cell “a”. In this case, verify levels VA+α, Vb+α, . . . , VG+α which are slightly higher than the foregoing verify levels VA, Vb, . . . , VG are used.

Next, in (4), when the second writing is performed in the memory cell “b”, the threshold voltage distribution of the memory cell “a” shifts to the original level due to capacitance coupling.

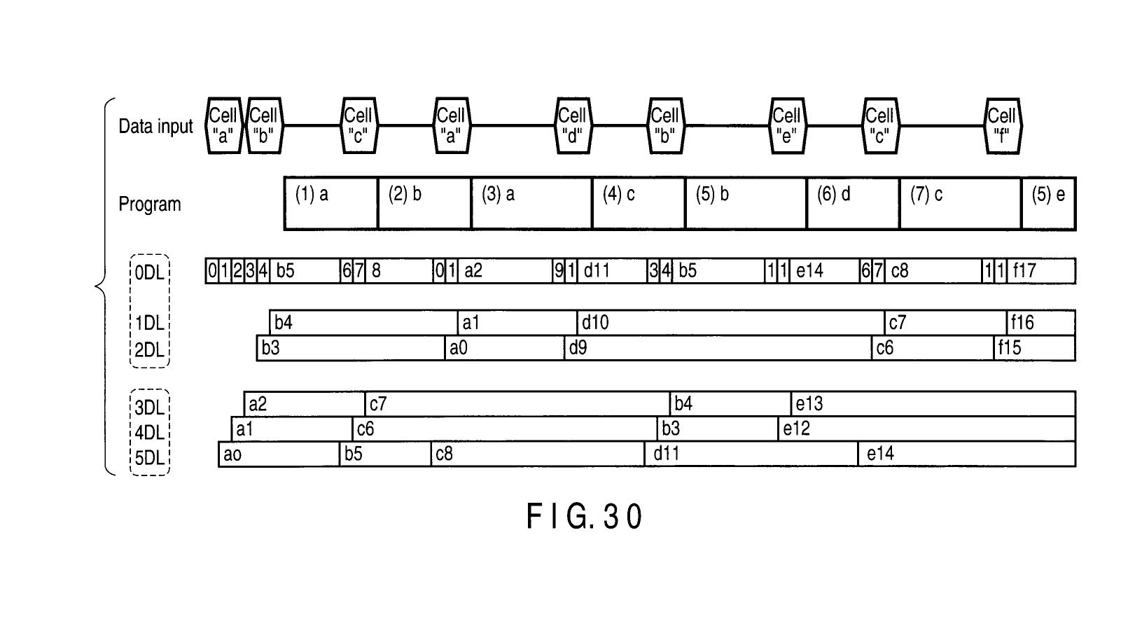

FIG. 30 shows a writing order of a sixth embodiment, and the same components as those of FIG. 28 are designated by identical symbols. In FIG. 30, the symbols of the “a0”, etc., described in correspondence with each latch circuit 0DL-5DL have the same meanings as those of FIG. 27.

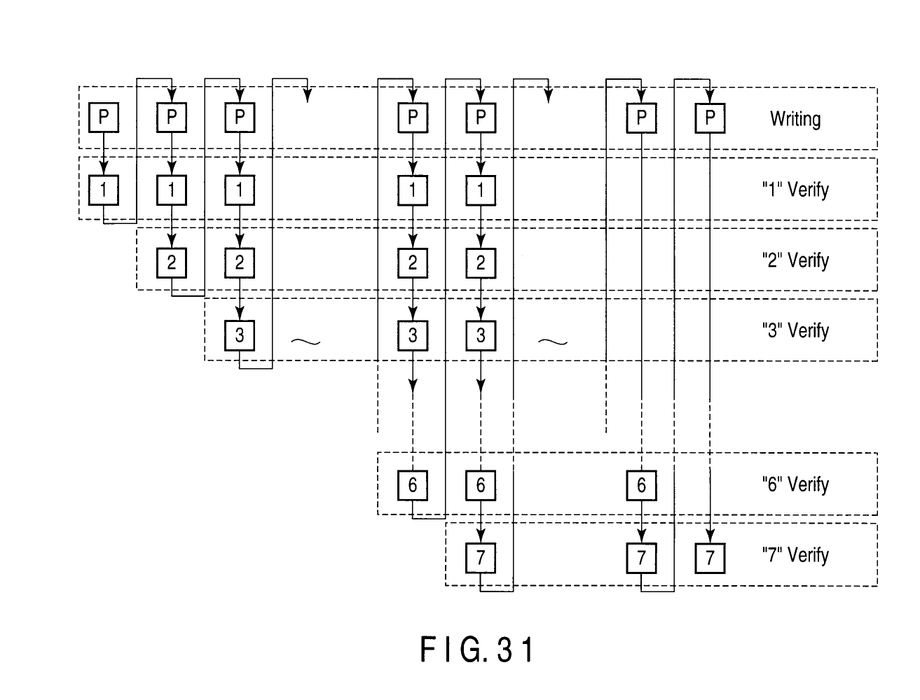

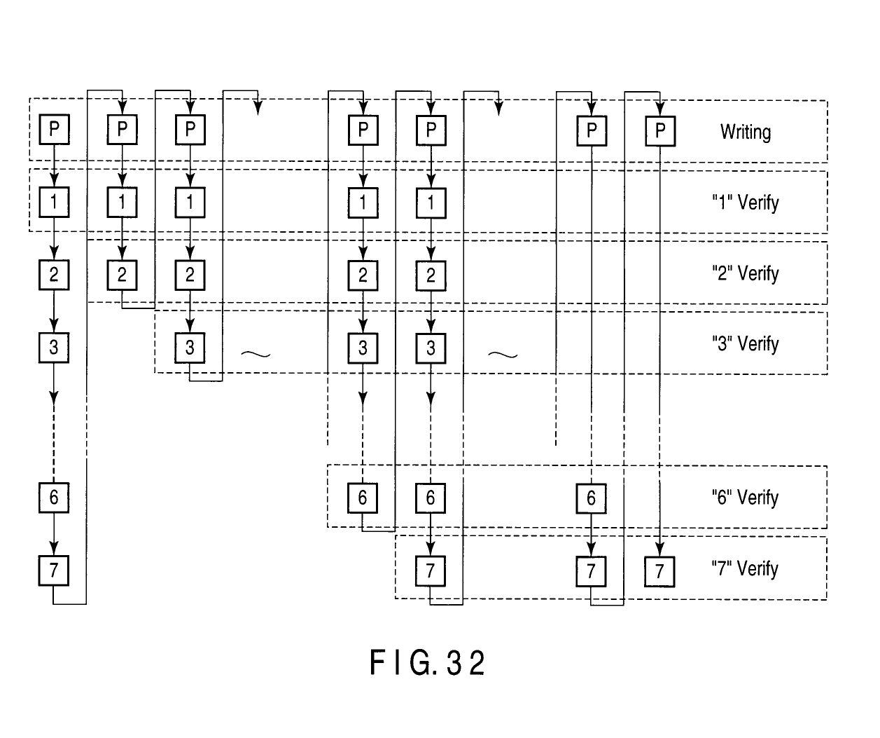

FIG. 31 shows the first program and verification sequence, and FIG. 32 shows the second program and verification sequence.

As shown in FIG. 31, at the initial phase of the writing, since data is not written in memory cells of which the threshold voltages are high, the verifications for the cells with higher threshold voltages are omitted. As the writing progresses, the verify operations increase. At the final phase of the writing, since the data has been already written in the cells with lower threshold voltages, the verifications in the cells with the lower threshold voltages are omitted.

While the second program and the verification sequence shown in FIG. 32 operate in the same manners as those of FIG. 31, the entire verification is performed only at the first writing.

According to the sixth embodiment, the data writing for a single memory cell is performed twice based on the coupling capacitance of memory cells adjacent to each other. Therefore, each threshold voltage distribution is precisely set to the memory cells.

### Seventh Embodiment

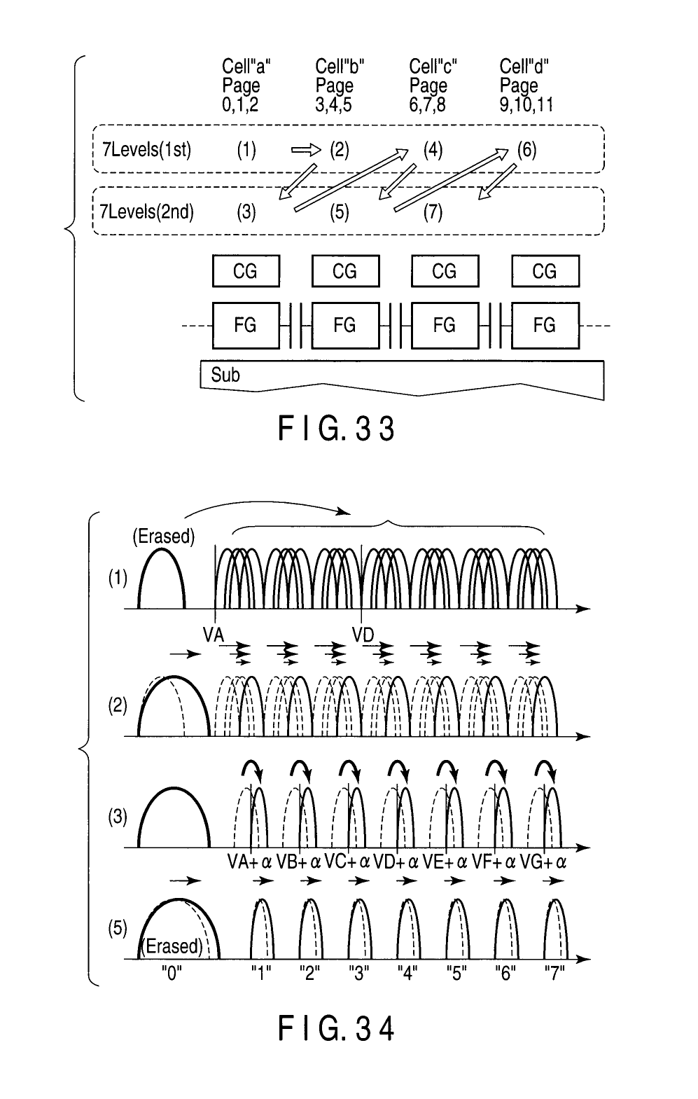

FIGS. 33, 34 show a seventh embodiment. The seventh embodiment is a modification of the forth embodiment. The fourth embodiment verifies the threshold voltage corresponding to two-bit data by using one verify level. After this, the fourth embodiment converts the writing data and the next writing data into the remaining number of times of writing.

Meanwhile, the seventh embodiment verifies the threshold voltage corresponding to 3-bit data by using two verify levels, and after this, the seventh embodiment converts the writing data and the next writing data into the remaining number of times of writing.

As shown in FIG. 33, in a way similar to the sixth embodiment, the seventh embodiment writes the 3-bit data in the single memory separately twice. That is, firstly, in (1), the 3-bit data is written in the memory cell “a”. Then, in (2), the 3-bit data is written in the memory cell “b” connected to the next word line. Next, in (3), the 3-bit data is written again in the memory cell “a”. Then, in (4), the 3-bit data is written in the memory cell “c” connected to the word cell distant by two from the word line to which the memory cell “a” is connected. After this, in (5), the 3-bit data is written in the memory cell “b” connected to the word line adjacent to the word line to which the memory cell “a” is connected.

FIG. 34 shows a change in threshold voltage distribution in the memory cell “a”. In (1), firstly, the 3-bit data is written in the memory cell “a”. Then, the data is verified by using, for example, the verify levels VA, VD. As a result, if the verification is passed, the writing data and the next writing data are converted into the remaining number of times of writing. In this case, the remaining number of times of writing is set to 3 times at a maximum in the same manner as that of the sixth embodiment. In this way, the remaining writing operations are executed, and the threshold voltage is set to an approximate level.

Next, in (2), when the data is written in the memory cell “b”, the capacitance coupling shifts the threshold voltage distribution.

Then, in (3), the memory cell “a” executes again the writing operation through the 3-bit data. In this case, the verify levels VA+α, Vb+α, . . . , VG+α which are slightly higher than the verify levels VA, Vb, . . . , VG are used.

Next, in (4), when the second writing is performed in the memory cell “b”, the capacitance coupling makes a shift of the threshold voltage distribution of the memory cell “a” to the original level.

According to the seventh embodiment, since 3-bit data can be written by using the two verify levels, the verification may be speeded up. And also, since the remaining number of times is set to 3 times as a maximum, the writing speed may be speeded up.

The data writing in a single memory cell is performed twice based on the coupling capacitance of memory cells adjacent to each other. Therefore, each threshold voltage distribution may be precisely set to the memory cells.

### Eighth Embodiment

While each of the aforementioned embodiments has been described based on the case in which the capacitance coupling due to the data to be written in the memory cells connected to adjacent word lines is compensated, in a single NAND unit. Meanwhile, an eighth embodiment describes compensation of capacitance coupling due to data to be written in the adjacent cells connected to a single word line.

Hereinafter, a case in which the data to be written in a single memory cell is 2-bit data will be described. However, the same compensation method may be used for the data of 3 or more bits.

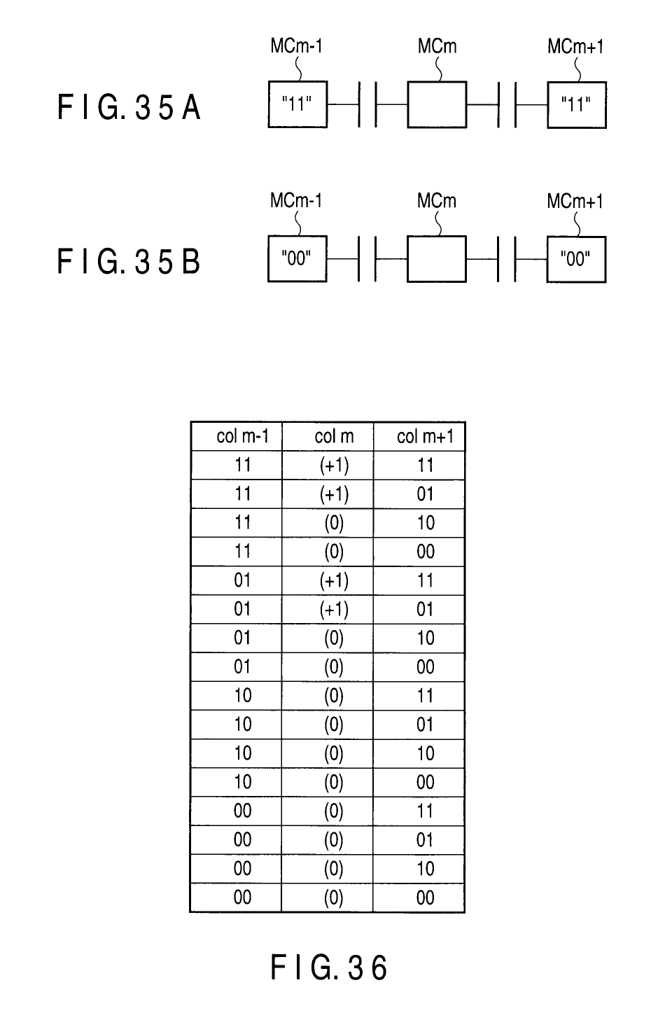

FIG. 35A shows a relationship among the threshold voltages of three memory cells connected to the identical word line. For instance, in a case in which the data is written in a memory cell MCm, if memory cells MCm−1 and MCm+1, which are neighboring memory cells of the memory cell MCm, are in an erasure state “11”, the memory cell MCm does not generate the shift of the threshold voltage due to the coupling capacitance of memory cells adjacent to each other.

Meanwhile, as shown in FIG. 35B, if the memory cells MCm−1 and MCm+1, which are neighboring memory cells of the memory cell MCm, have threshold voltages higher than those in the erasure state, for example, “00”, the threshold voltage is shifted due to the coupling capacitance of memory cells adjacent to each other when the data is written in the memory cell MCm.

The compensation method of the eighth embodiment compensates the acceptance of coupling of memory cells adjacent to each other by additionally writing the data after the completion of the writing in response to the data in the memory cell in the adjacent columns. However, since the data in the adjacent columns is of various, the number of times of additional writing of the data is set depending on the relationship among the data items.

FIG. 36 shows the relationships among the data of the adjacent columns and the number of items of the additional writing. As shown in FIG. 36, if both items of the data in two memory cells adjacent to the memory cell to be written are “11”, if the data in one memory cell is “11” and the data in the other memory is “01”, or if both the items of data in the two memory cells adjacent to each other are “10”, control is performed so as to additionally write the data at one time. In FIG. 36, (+1) indicates that one-time additional writing is performed, and “0” indicates that additional writing is not performed.

FIG. 37 shows a method for detecting columns in which additional writing is needed. FIG. 37 shows only columns from a column 1 (col 1) to a column 10 (col 10) as an example.

Data is loaded from the outside, for example, on the data latch circuits 1DL, 2DL of each column (here, they are shown as the data control units DCUs), respectively. That is, the data “01” is loaded on the data latch circuit in the column 1, and the data “10” is loaded on the data latch circuit in the column 2.

Next, as shown in a row of “Lower”, the data of a lower bit in each column is loaded. At this moment, as shown, for example, by “(a) col shift +”, firstly, the data of the lower bit shifted in a column direction of a higher order by one column is loaded, for example, on the data latch circuit 3DL. At this moment, the data “1” is set in the column 1 having no corresponding-data.

After this, as shown in a row of “(b) col shift-”, the data of the lower bit is shifted in a column direction of a lower order by one column, and is loaded, for example, on the data latch circuit 4DL. In this way, data of the neighbors of the column can be made to correspond to each column by loading the data which has shifted to a higher order by one column and to a lower order by one column. At this time, the data “1” is set in the column 10 having no corresponding-data.

In this way, after loading the data three times from the outside, a “NAND” logic between the data which has been shifted in a higher order direction and the data which has been shifted in a lower order direction is computed as shown by /((a) & (b)). Based on the result of the computation, the additional writing is performed. That is, the additional writing to the column 2 and column 5 with the data “0” is performed, and the additional writing is not performed to other columns. QPW indicates a column to which additional writing is performed.

According to the eighth embodiment, in a plurality of memory cells connected to one word line, a semiconductor memory device detects columns to which additional writing is needed on the basis of the data in the adjacent memory cells, and enables only the necessary columns to be additionally written. Therefore, the compensation method can compensate the shift of the threshold voltage based on the coupling capacitance of memory cells adjacent to each other in the word line direction.

In each embodiment given above, the remaining number of times of writing is not limited to the given examples. It is well known that, in the NAND flash memory, repeating the writing and erasing increase a shift amount of the threshold voltages against a program voltage. Therefore, it is preferable to reduce the remaining number of times of writing. This control may be done in such a manner that, for example, a controller (not shown) counts the number of times of writing and erasing, and when the counted number reaches a defined value, the controller controls the memory device to decrease the remaining number of times of writing.

(Modification Example of Sense Amplifier Unit)

As mentioned above, controlling the electrical potential in the bit line for writing enables setting the remaining number of times of programming to a small number multiple. This control is performed by using a sense amplifier unit.

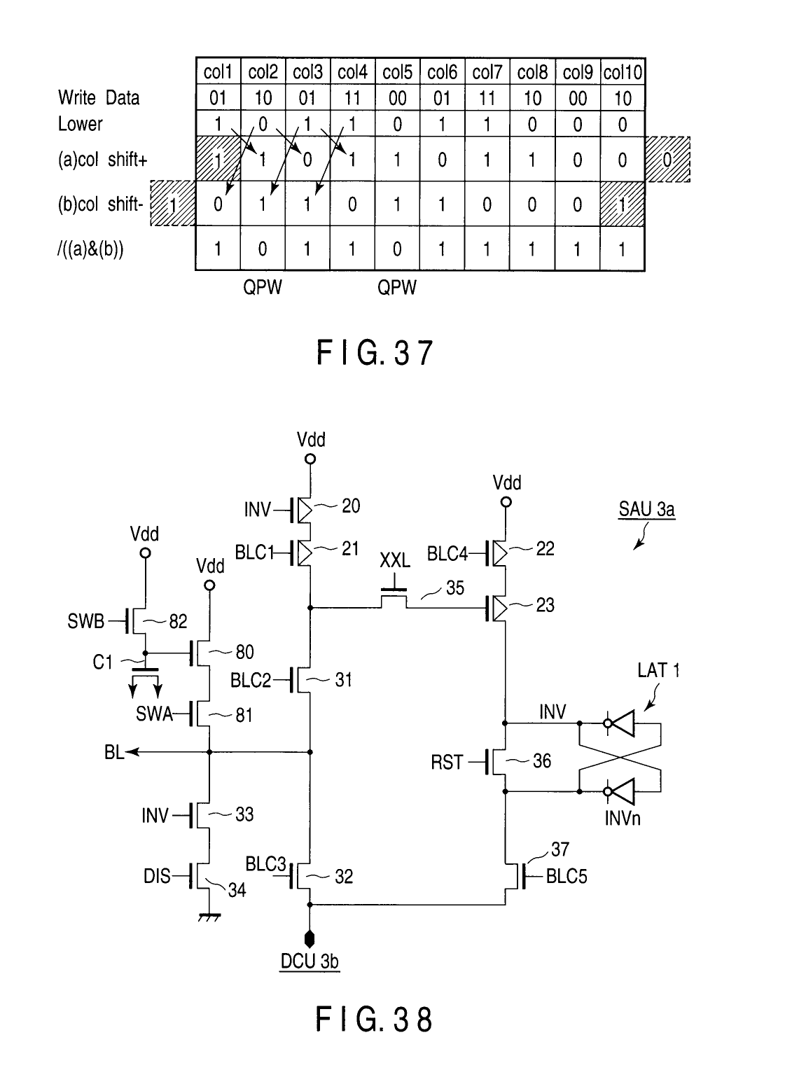

FIG. 38 shows a modification example of the sense amplifier unit 3a shown in FIG. 3. In FIG. 38, the same components as those of FIG. 3 are designated by identical symbols, and only different components will be described.

In FIG. 38, NMOSs 80, 81 are serially connected between a node to which the power source voltage Vdd is supplied and the bit line BL. The gate of the NMOS 80 is connected to the node to which the power source voltage Vdd is supplied through the NMOS 82, and is connected to one end of a capacitor C1. The other end of the capacitor C1 is grounded. A signal SWA is supplied to the gate of the NMOS 81, and a signal SWB is supplied to the gate of the NMOS 82.

(Example of Defined Electric Charge as Analog Value to be Supplied to Capacitor)

In the program operation in each of the foregoing embodiments, setting the signal BLC2 in FIG. 3 to an intermediate electrical potential enables realizing the writing of 0.5 times, which is equivalent to half of a writing pulse, for cells exceeding the verify level.

Meanwhile, in the case of the modification example shown in FIG. 38, necessary electrical potentials can be generated in response to the charged electric charges in the capacitor C1. That is, if the signal SWB is set to the H level, the NMOS 82 turns on, and the electric charges are accumulated in the capacitor C1 through this NMOS 82. The signal SWB enables controlling an on period of the NMOS 82, and controlling the charged electric charges in the capacitor C1.

In this state, setting the signal SW to the H level turns on the NMOS 81. The NMOS 80 is turned on in response to the electric charges accumulated in the capacitor C1. Therefore, the electrical potential may be supplied to the bit line BL through the NMOSs 80, 81. This electric potential is controlled in response to the charged electric charges in the capacitor C1. That is, controlling the charged electric charges in the capacitor C1 enables supplying a necessary intermediate electrical potential to the bit line BL. An optimum pulse equivalent to a writing pulse of the number of times of one or less can be supplied to the memory cell.

(Example of Back Pattern Compensation)

Next, back pattern completion, varying its intermediate electrical potential in response to the data to be written next in a block, will be described.

In each of the foregoing embodiments, the influence of coupling capacitance of memory cells adjacent to each other is compensated by completing the writing in response to the data to be written in the adjacent memory cell, and by applying several writing pulses to write the data at a target level.

Meanwhile, in the case of back pattern completion, it is necessary to control the writing in response to the data to be written in the block. That is, as shown in FIG. 2, after the data is written in the memory cells connected to a certain word line WLn, the data is written in the memory cells connected to the word lines WLn+1−WL31. Here, if there are many cells in which the data “00” is written, electric currents are reduced in verify reading and in reading. Therefore, a problem is posed in which a threshold level of a cell, being connected to the word line on which the data has been written previously, appears to become slightly high.

If the data to be written in the cells connected to the word lines WLn+1-WL31 have mostly low levels, and mostly do not have high levels, writing the data at a level higher than the original verify level in advance enables correcting the back pattern in the block.

More specifically, the total points of the data to be written in the word lines WLn+1 to WL31 can be obtained, for example, by setting three points if the data to be written in the word line WLn+1 to WL31 is “11”, by setting two points if the data is “01”, and by setting one point if the data is “10”, and by setting zero points if the data is “00”. After this, the total points are divided by the number of the word lines WLs to be averaged. This computation is executed, for example, by an external controller (host device) (not shown).

For writing the data in the word line WLn, the averaged points computed by the controller are sent to a semiconductor memory device, and additional writing voltage pulses are supplied in response to the averaged points for the memory cells which have reached the verify level. That is, the higher the averaged points are, the larger the amount of voltage pulses supplied. In this case, for the simplify, it is possible to reduce the number of pulses to several times, such as 0 times, 0.5 times, 1 time, and 1.5 times of four patterns, for example.

In this way, compensating the threshold voltages to be previously written in response to states of the data to be written in the block enables correcting the back pattern in the block.

Similarly to each embodiment, the writing voltage pulse may be supplied at less than one time by applying an intermediate voltage to the bit line.

(Example of a Case where No Next Writing Data Exists)

In each of the foregoing embodiments, there is a case where no data to be written in adjacent cells may exist when data is written in memory cells. That is, in a case where, for example, 2-bit (2 pages) data is written in a single memory cell, both the first bit data and the second bit data may not exist, or no dada of the second bit may exist. Or, in a case where 3-bit (3 pages) data is written in a single memory, all the 3-bit data items may not exist, or the data after the second bit may not exist. In such a case, an external controller of the semiconductor memory device, for example, a host device generates dummy data, and the dummy data is supplied to the semiconductor memory device to be written in the memory cells. This dummy data may set the data of 2-bit (2 pages) or more to, for example, all “1” or all “0”, and may set the data of 2-bit (2 pages) or more to, for example, an arbitrary value such as “01” or “10”. That is, the data after writing may be set to not less than the erasure level, and may be set to the lowest level, the highest level of the threshold level, or an intermediate level.

In this way, the writing of the dummy data enables accurately setting the threshold levels of the memory cells in which the data is previously written even if no data exists in the adjacent cells.

(Example of Application)

Next, an application to which the aforementioned semiconductor memory is applied will be described.

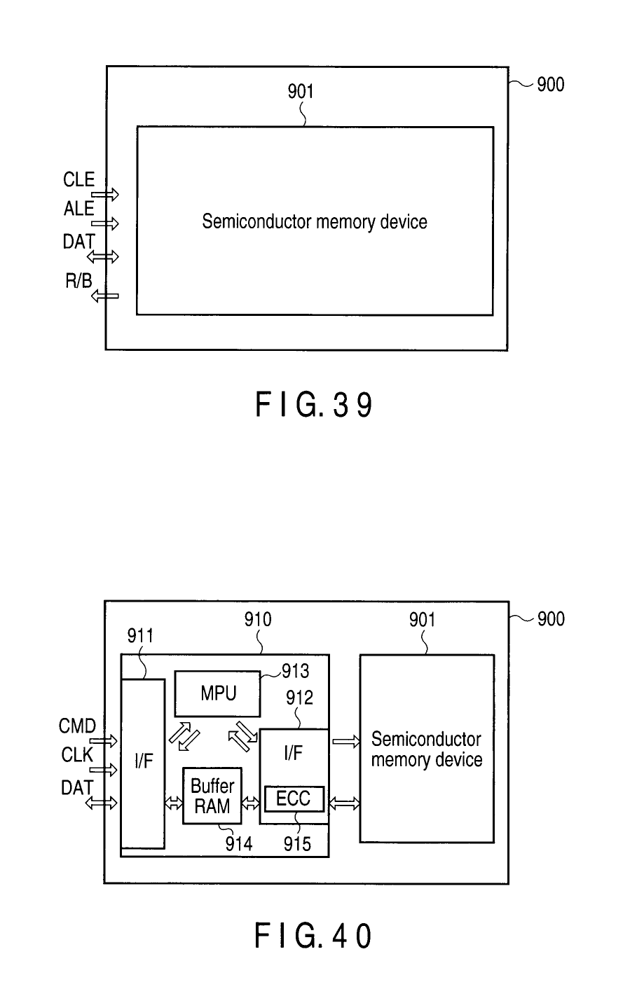

FIG. 39 shows an example of a memory card to which the semiconductor memory device is applied. In FIG. 39, a memory card 900 includes a NAND flash memory 901 described in the foregoing embodiments. The semiconductor memory device 901 receives a predetermined control signal and data from an external device (not shown). The semiconductor memory device 901 outputs the predetermined control signal and the data to the external device (not shown).

That is, the semiconductor memory device 901 mounted on the memory card 900 is connected to a signal line (DAT) for transferring data, a address or a command; a command line enable signal (CLE) indicating the transfer of the command to the signal line DAT; an address line enable signal line (ALE) indicating the transfer of the address to the signal line DAT; and a ready/busy signal line (R/B) indicating whether or not a flash memory (parameter memory unit) 10 is operable.

FIG. 40 shows an example of another memory card. This memory card is different from the memory card shown in FIG. 40, controls the flash memory, and has an external device (not shown) and controller 910.

The controller 910 includes an interface unit 911, for example, for inputting a signal from an external device (not shown) or for outputting a signal to the external device; an interface unit 912 for transmitting/receiving a signal to/from the semiconductor memory device 901 including the NAND flash memory; a microprocessor (MPU) 913 for computing involved in, for example, converting a logical address input from the external device into a physical address; a RAM 914 as a buffer for temporarily storing the data; and an error correction unit (ECC) 915 for generating an error correction code. A command signal line (CMD), a clock signal line (CLK) and a signal line (DAT) are connected to the interface unit 911 of the memory card 900.

In the memory card, the number of various signal lines, bit widths of the signal lines and a configuration of a controller are modifiable. Applying this configuration enables configuring a solid state drive (SSD) as a substitute for a hard disk drive.

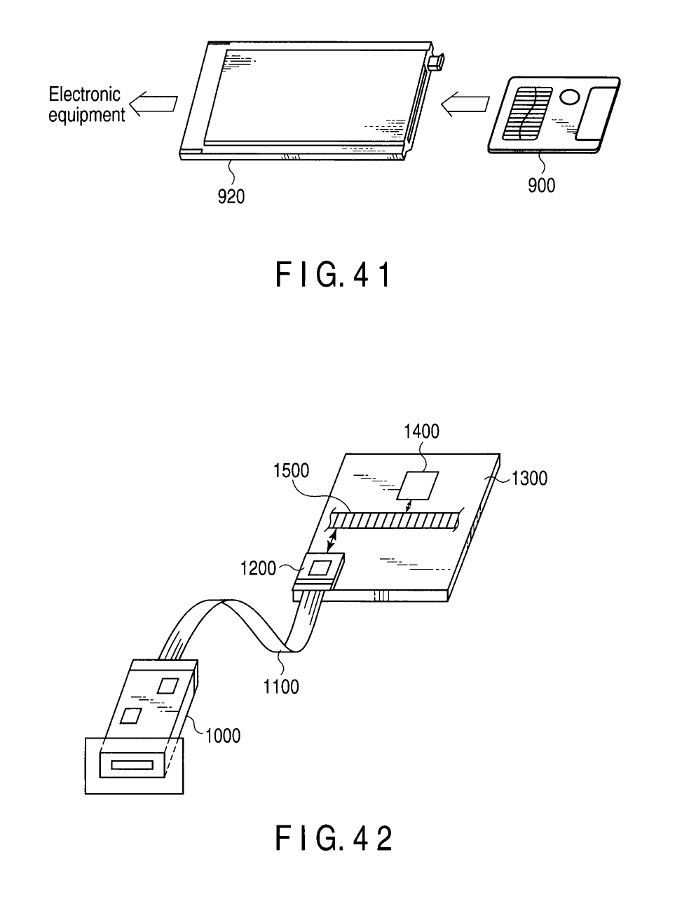

FIG. 41 shows another application. As shown in FIG. 41, the memory card 900 is inserted into a card holder 920 and is connected to electronic equipment (not shown). The card holder 920 may have a part of a function of the controller 910.

FIG. 42 shows another application. A memory card 900 or the card holder 920, into which the memory card 900 is inserted, is inserted into a connection device 1000. The connection device 1000 is connected to a board 1300 through a connection wiring 1100 and an interface circuit 1200. A CPU 1400 and a bus 1500 are mounted on the board 1300.

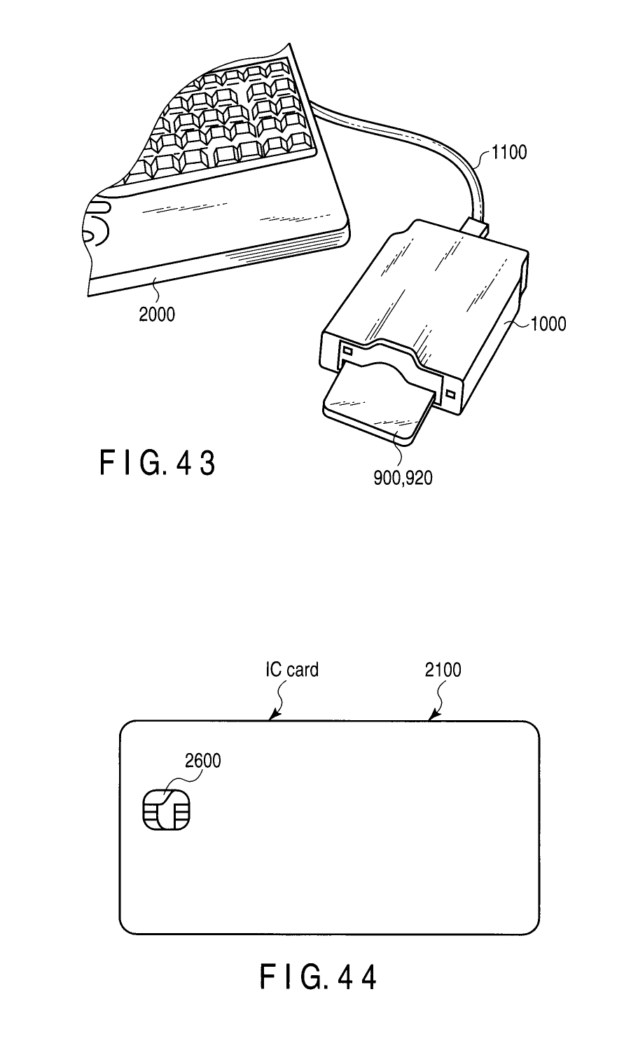

FIG. 43 shows another application. The memory card 900 or the card holder 920, into which the memory card 900 is inserted, is inserted into the connection device 1000. The connection device 1000 is connected to a personal computer 2000 through the connection wiring 1100.

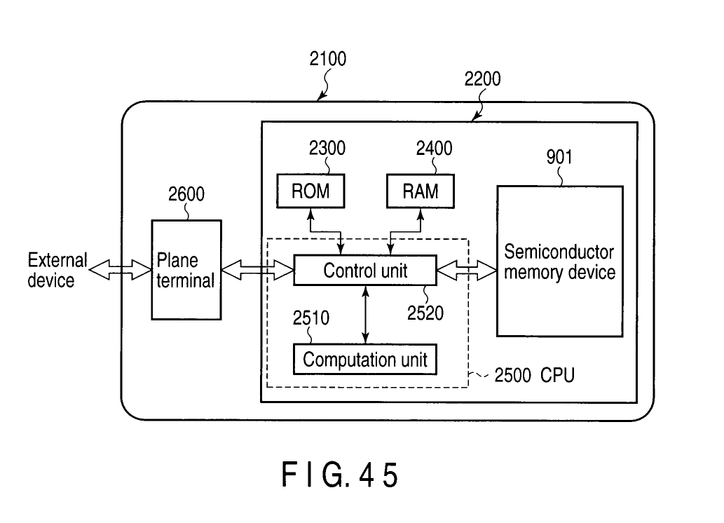

FIGS. 44 and 45 show other applications. As shown in FIGS. 44 and 45, an IC card 2100 mounts an MCU 2200. The MCU 2200 includes a semiconductor memory device 901 including a NAND flash memory according to the given embodiments, and, for example, a ROM 2300, a RAM 2400 and a CPU 2500. The IC card 2100, as shown in FIG. 44, has a plane terminal 2600 exposed on the surface of the IC card 2100, and the plane terminal 2600 is connected to the MCU 2200. The CPU 2500 includes a computation unit 2510, and a control unit 2520 connected to the flash memory 3, a ROM 2300 and RAM 2400.

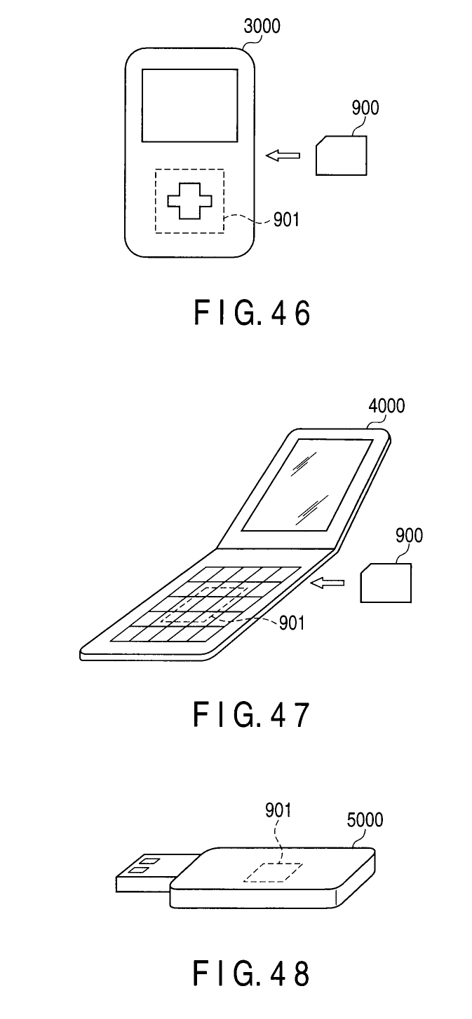

FIG. 46 shows another application, and shows, for example, an example of a mobile music record/reproduction device 3000. The device 3000 has, for example, a built-in semiconductor memory device 901, in a main unit, including a NAND flash memory according to the foregoing embodiments. Further, the memory card 900 including a NAND flash memory can be mounted on the device 3000.

FIG. 47 shows another application, and shows, for example, a mobile terminal device 4000 such as a cellular phone. The mobile terminal device 4000 has a built-in semiconductor memory device 901, in a main unit, including a NAND flash memory according to the aforementioned embodiments. Further, the memory card 900 including the NAND flash memory can be mounted on the device 4000.

FIG. 48 shows another application, and shows, for example, a USB memory 5000. The USB memory 5000 has a built-in semiconductor memory device 901 in a main unit, and includes a NAND flash memory according to the foregoing embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a memory cell array in which a plurality of memory cells connected to a word line and a bit line are arranged in a matrix, each of the plurality of memory cells of which stores one value out of n values (n is a natural number of 2 or more); and
a control circuit configured to control electrical potentials of the word line and the bit line in response to input data, and to write data in the memory cells, wherein:
when writing the data in a first memory cell of the memory cell array, the control circuit varies a writing level on the basis of writing data to write in a second memory cell adjacent to the first memory.

2. The device according to claim 1, further comprising:
a first data latch configured to hold writing data in the first memory cell; and
a second data latch configured to hold the writing data in the second memory cell.

3. The device according to claim 1, wherein:
when the first and the second memory cells store one level of n levels of “0” level (erase level) . . . “(n−1)” level (“0” level<“(n−1)” level) as data, and when writes “k” level (k is 0 to (n−1)) in the first memory cell, if the writing data in the second memory is “0” level, if the writing data is “1” level, and if the writing data is “k_{—}1” level, . . . , “(n−1)” level, the writing data is written in “k_{—}0” level, in “k_{—}1” level, and in “k (n−1)” level (“k_{—}0” level=>“k_{—}1” level=>, . . . , =>“K_(n−1)” level), respectively.

4. The device according to claim 3, wherein
the control circuit verifies the data at a “k_h” level (h is 0 to (n−1)) after writing the data in a “k” level (k is 0 to (n−1)) in the first memory, and for writing data in other than the “k_h” level, writes the data in a “k_h+1” level, and in a “k_h+2” level, . . . , “k (n−1)” level by applying a writing voltage to the first memory cell by the number of times based on the data in the second memory cell after the data exceeds the “k_h” level.

5. The device according to claim 3, wherein:
the control circuit verifies the data at a “k_h” level (h is 0 to (n−1)) after writing the data in a “k” level (k is 0 to (n−1)) in the first memory, and writes the data in a “k_h+1” level, and in a “k_h+2” level, . . . , a “k_i)” level (i is 0 to (n−1)) by applying a writing voltage to the first memory cell by the number of times based on the data in the second memory cell after the data exceeds the “k_h” level (h is 0 to (n−1)).

6. The device according to claim 3, wherein:
when writing the data in the first memory cell, if writing data to write in the second memory cell is not defined yet, the control circuit writes the data at a “k_(n−1)” level for writing the data in a “k” level (k is 0 to (n−1)) in the first memory cell.

7. The device according to claim 3, wherein:
when writing the data in the first memory cell, if writing data to write in the second memory cell is not defined yet, the control circuit writes the data in a “k_i” level (i is any one of 0, 1, . . . , (n−1)) for writing the data in a “k” level (k is 0 to (n−1)) in the first memory cell.

8. A program method of a semiconductor memory device for storing one value out of n values (n is a natural number of 2 or more), respectively, in a plurality of memory cells which are arranged in a matrix, comprising:
writing data in a first memory cell of the memory cell array in response to input data; and
varying a verify level on the basis of writing data to write in a second memory adjacent to the first memory.

9. The method according to claim 8, wherein:
when the first and the second memory cells store data in one level among “0” level (erasure level) and n values out of “1” level to “(n−1)” level (“0” level<“(n−1)” level), and when writing “k” level (k is 0 to (n−1)) in the first memory cell, if the writing data in the second memory is “0” level (erasure level), and if the writing data is “1” level, and if the writing data is “k_{—}1” level, . . . , “(n−1)” level, the writing data is written in “k_{—}0” level, “k_{—}1” level, and “k (n−1)” level (“k 0” level=>“k_{—}1” level=>, . . . , =>“K (n−1)” level), respectively.

10. The method according to claim 9, wherein
the control circuit verifies the data at a “k_h” level (h is 0 to (n−1)) after writing the data in a “k” level (k is 0 to (n−1)) in the first memory; and writes the data in a “k_h+1” level, a “k_h+2” level, . . . , a “k_i)” level (h is 0 to (n−1)) by applying a writing voltage to the first memory cell by the number of times based on the data in the second memory cell after the data exceeds the “k_h” level (h is 0 to (n−1)).

11. The method according to claim 9, wherein
the control circuit verifies the data at a “k_h” level (h is 0 to (n−1)) after writing the data in “k” level data (k is 0 to (n−1)) in the first memory; and writes the data at a “k_h+1” level, a “k_h+2” level, . . . , a “k_i)” level (i is 0 to (n−1)) by applying a writing voltage to the first memory cell by the number of times based on the data in the second memory cell after the data exceeds the “k_h” level (h is 0 to (n−1)).

12. The method according to claim 9, wherein:
when writing the data in the first memory cell, if writing data to write in the second memory cell is not defined yet, the control circuit writes the data in a “k (n−1)” level for writing the data in a “k” level (k is 0 to (n−1)) in the first memory cell.

13. The method according to claim 9, wherein:
when writing the data in the first memory cell, if writing data to write in the second memory cell is not defined yet, the control circuit writes the data in a “k_i” level (i is any one of 0, 1, . . . , (n−1)) for writing the data in a “k” level (k is 0 to (n−1)) in the first memory cell.

14. A memory card including the semiconductor memory device according to claim 1.

15. The memory card according to claim 14, wherein
the memory card further includes a controller.

16. A card holder on which the memory card according to claim 15 is mounted.

17. A portable electronic device including the semiconductor memory device according to claim 14.

18. A portable electronic device on which the memory card according to claim 15 is mounted.

19. A universal serial bus (USB) memory including the semiconductor memory device according to claim 1.
